(19) United States
(12) Patent Application Publication
(10) Pub. No.: US 2024/0334722 A1
(43) Pub. Date: Oct. 3, 2024

(54) DISPLAY DEVICE AND METHOD FOR MANUFACTURING DISPLAY DEVICE

(71) Applicant: Sharp Display Technology Corporation, Kameyama City, Mie (JP)

(72) Inventors: Ryo KITAMURA, Kameyama City, Mie (JP); Takahiro ADACHI, Kameyama City, Mie (JP); Yukio TAKENAKA, Kameyama City, Mie (JP); Yuma YAGUCHI, Kameyama City, Mie (JP)

(21) Appl. No.: 18/693,808

(22) PCT Filed: Nov. 24, 2021
(86) PCT No.: PCT/JP2021/042951

§ 371 Date: Mar. 20, 2024

(51) Int. Cl. H10K 50/115; H10K 71/15

(52) U.S. Cl. CPC H10K 50/115; H10K 71/15

(57) ABSTRACT

A display device includes the following: a first light-emitting layer including a first inorganic matrix and a first quantum dot; and a self-assembled monolayer composed of monomolecules adjacent to each other, and having a surface that exhibits liquid repellency against a polar solvent, the monomolecules each having a distal end on one side that is a non-polar functional group.

### TECHNICAL FIELD

The present disclosure relates to a display device and a method for manufacturing a display device.

### BACKGROUND ART

Display devices provided with quantum-dot light-emitting diodes (QLEDs), which are light-emitting elements, have received considerable attention recently.

However, it is known that quantum dots included in a QLED's light-emitting layer deteriorate increasingly due to moisture entrance; studies have been made actively for preventing such deterioration resulting from moisture entrance.

For instance, Patent Literature 1 describes encapsulating quantum dots by the use of a layer of metal nitride or metal oxide.

### CITATION LIST

### Patent Literature

Patent Literature 1: United States Unexamined Patent Application Publication No. 2018/0196164A1

### SUMMARY

### Technical Problem

However, Patent Literature 1 describes only forming, onto the entire surface, a layer of metal nitride or metal oxide for encapsulating quantum dots. For producing a display device provided with a red light-emitting layer including quantum dots, a green light-emitting layer including quantum dots, and a blue light-emitting layer including quantum dots by the use of such a method, the red light-emitting layer including the quantum dots, the green light-emitting layer including the quantum dots, and the blue light-emitting layer including the quantum dots are formed firstly, followed by the layer of metal nitride or metal oxide for encapsulating these quantum dots. Thus, in forming the red light-emitting layer including quantum dots, the green light-emitting layer including quantum dots, and the blue light-emitting layer including quantum dots in the stated order for instance, the quantum dots included in the red light-emitting layer is unfortunately damaged in each of the process step of forming the green light-emitting layer including the quantum dots, and the process step of forming the blue light-emitting layer including the quantum dots, and the quantum dots included in the green light-emitting layer is unfortunately damaged in the process step of forming the blue light-emitting layer including quantum dots.

Furthermore, a liftoff method is often used in the foregoing process step of forming the red light-emitting layer including the quantum dots, the foregoing process step of forming the green light-emitting layer including the quantum dots, and the foregoing process step of forming the blue light-emitting layer including the quantum dots. In such a case, each process step of forming the light-emitting layer of the corresponding color includes a process step of developing a resist layer, and a process step of removing the resist layer as essential process steps, thus making it difficult to simplify manufacturing process steps.

One aspect of the present disclosure has been made in view of this problem and aims to provide a method for manufacturing a display device that can reduce damage on quantum dots and simplify manufacturing process steps, and to provide such a display device.

### Solution to Problem

To solve the above problem, a method for manufacturing a display device of the present disclosure includes the following steps:
forming a self-assembled monolayer using a self-assembled monomolecule whose distal end on one side is a non-polar functional group onto a polar surface of an underlayer to form a non-polar region that is a surface of the self-assembled monolayer;
forming a first polar surface region that is the polar surface of the underlayer, by light irradiation to remove a part of the self-assembled monolayer;
forming a first-quantum-dot application solution containing a first quantum dot, a first inorganic material precursor, and a polar solvent selectively in the first polar surface region; and
after the step of forming the first-quantum-dot application solution, forming a first light-emitting layer including the first quantum dot embedded in a first inorganic matrix composed of the first inorganic material precursor, by performing at least one of heating and light irradiation.

To solve the above problem, a display device in the present disclosure includes the following:
a first light-emitting layer including a first quantum dot embedded in a first inorganic matrix; and
a molecular film composed of molecules adjacent to each other, and having a non-polar surface, the molecules each having a distal end on one side that is a non-polar functional group.

To solve the above problem, a display device in the present disclosure includes the following:
a first light-emitting layer including a first quantum dot embedded in a first inorganic matrix;
a second light-emitting layer including a second quantum dot embedded in a second inorganic matrix; and
a third light-emitting layer including a third quantum dot embedded in a third inorganic matrix,
wherein a band gap of the third quantum dot is larger than a band gap of the first quantum dot, and a band gap of the second quantum dot,
the band gap of the second quantum dot is larger than the band gap of the first quantum dot,
a valence band maximum of the first inorganic matrix is deeper than a valence band maximum of the first quantum dot,
a conduction band minimum of the first inorganic matrix is shallower than a conduction band minimum of the first quantum dot,
a valence band maximum of the second inorganic matrix is deeper than a valence band maximum of the second quantum dot,
a conduction band minimum of the second inorganic matrix is shallower than a conduction band minimum of the second quantum dot,
a valence band maximum of the third inorganic matrix is deeper than a valence band maximum of the third quantum dot,
a conduction band minimum of the third inorganic matrix is shallower than a conduction band minimum of the third quantum dot,
the conduction band minimum of the third inorganic matrix is shallower than the conduction band minimum of the first inorganic matrix, and the conduction band minimum of the second inorganic matrix, and
the conduction band minimum of the second inorganic matrix is shallower than the conduction band minimum of the first inorganic matrix.

### Advantageous Effect of Invention

The aspects of the present disclosure can provide a method for manufacturing a display device that can reduce damage on quantum dots and simplify manufacturing process steps, and the aspects can provide such a display device.

### BRIEF DESCRIPTION OF DRAWINGS

FIG. 1 is a plan view of a schematic configuration of a display device according to a first embodiment.

FIG. 2 is a sectional view of a schematic configuration of a substrate included in the display device according to the first embodiment, and including transistors.

FIG. 3 is a sectional view of a schematic configuration of light-emitting elements included in the display device according to the first embodiment.

FIG. 4(a), FIG. 4(b), FIG. 4(c), and FIG. 4(d) illustrate some of process steps for manufacturing the display device according to the first embodiment.

FIG. 5(a), FIG. 5(b), and FIG. 5(c) illustrate some of the process steps for manufacturing the display device according to the first embodiment that are performed after the process step illustrated in FIG. 4(d).

FIG. 6(a), FIG. 6(b), and FIG. 6(c) illustrate some of the process steps for manufacturing the display device according to the first embodiment that are performed after the process step illustrated in FIG. 5(c).

FIG. 7(a), FIG. 7(b), and FIG. 7(c) illustrate some of the process steps for manufacturing the display device according to the first embodiment that are performed after the process step illustrated in FIG. 6(c).

FIG. 8(a), FIG. 8(b), and FIG. 8(c) illustrate some of the process steps for manufacturing the display device according to the first embodiment that are performed after the process step illustrated in FIG. 7(c).

FIG. 9(a) and FIG. 9(b) illustrate some of the process steps for manufacturing the display device according to the first embodiment that are performed after the process step illustrated in FIG. 8(c).

FIG. 10 is a plan view of the surface of a self-assembled monolayer included in the display device according to the first embodiment.

FIG. 11 is a sectional view of a schematic configuration of light-emitting elements included in a display device according to a first modification of the first embodiment.

FIG. 12 is a sectional view of a schematic configuration of light-emitting elements included in a display device according to a second modification of the first embodiment.

FIG. 13 is a sectional view of a schematic configuration of light-emitting elements included in a display device according to a third modification of the first embodiment.

FIG. 14(a) is a sectional view of a schematic configuration of light-emitting elements included in a display device according to a second embodiment, and FIG. 14(b) is a sectional view of a schematic configuration of light-emitting layers included in the display device according to the second embodiment.

FIG. 15(a), FIG. 15(b), and FIG. 15(c) illustrate ideal band levels of a quantum dot and an inorganic matrix in the light-emitting layer of each color.

FIG. 16(a) and FIG. 16(c) illustrate an instance where the positional relationship between the band level of the quantum dot and the band level of the inorganic matrix is not ideal, and FIG. 16(b) illustrates an instance where the positional relationship between the band level of the quantum dot and the band level of the inorganic matrix is ideal.

FIG. 17 illustrates the band levels of respective oxides.

FIG. 18(a) is a sectional view of a schematic configuration of light-emitting elements included in a display device according to a third embodiment, and FIG. 18(b) is a sectional view of a schematic configuration of light-emitting layers included in the display device according to the third embodiment.

FIG. 19(a) is a sectional view of a schematic configuration of light-emitting elements included in a display device according to a fourth embodiment, and FIG. 19(b) is a sectional view of a schematic configuration of light-emitting layers included in the display device according to the fourth embodiment.

FIG. 20 is a sectional view of a schematic configuration of light-emitting elements included in a display device according to a fifth embodiment.

FIG. 21(a), FIG. 21(b), FIG. 21(c), and FIG. 21(d) illustrate some of process steps for manufacturing the display device according to the fifth embodiment.

FIG. 22(a), FIG. 22(b), and FIG. 22(c) illustrate some of the process steps for manufacturing the display device according to the fifth embodiment that are performed after the process step illustrated in FIG. 21(d).

FIG. 23(a), FIG. 23(b), and FIG. 23(c) illustrate some of the process steps for manufacturing the display device according to the fifth embodiment that are performed after the process step illustrated in FIG. 22(d).

FIG. 24(a), FIG. 24(b), FIG. 24(c), FIG. 24(d), FIG. 24(e), and FIG. 24(f) illustrate process steps of a liftoff method using a normal resist layer according to a comparative example.

FIG. 25(a), FIG. 25(b), FIG. 25(c), FIG. 25(d), FIG. 25(e), and FIG. 25(f) illustrate process steps of a liftoff method using a liquid-repellent resist layer according to a comparative example.

### BRIEF DESCRIPTION OF DRAWINGS

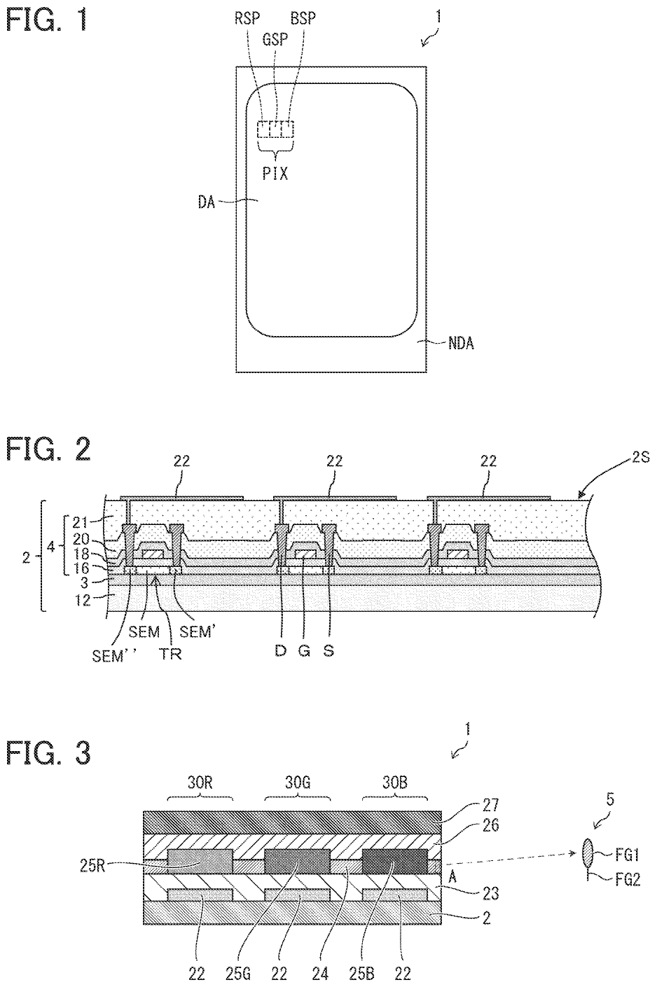

The following describes embodiments of the present disclosure on the basis of FIG. 1 through FIG. 25. Hereinafter, for convenience in description, a component having the same function as that of a component described in a particular embodiment will be denoted by the same sign, and its description will be omitted in some cases.

### First Embodiment

FIG. 1 is a plan view of a schematic configuration of a display device 1 according to a first embodiment.

As illustrated in FIG. 1, the display device 1 has a frame region NDA and a display region DA. The display region DA of the display device 1 is provided with a plurality of pixels PIX, and each pixel PIX includes a red subpixel RSP, a green subpixel GSP, and a blue subpixel BSP. This embodiment describes, by way of example, an instance where a single pixel PIX is composed of the red subpixel RSP, green subpixel GSP, and blue subpixel BSP. For instance, a single pixel PIX may further include a subpixel of another color other than the red subpixel RSP, green subpixel GSP, and blue subpixel BSP.

FIG. 2 is a sectional view of a schematic configuration of a substrate 2 included in the display device 1 according to the first embodiment, and including transistors TR.

As illustrated in FIG. 2, the substrate 2 included in the display device 1 and including the transistors TR (substrate) has a substrate 12 on which a barrier layer 3, and a thin-film transistor layer 4 including the transistors TR are provided in the stated order on the substrate 12. Moreover, the substrate 2 including the transistors TR has a surface 2S provided with first electrodes 22.

The substrate 12 may be, for instance, a resin substrate made of a resin material, such as polyimide, or a glass substrate. This embodiment describes, by way of example, an instance where the substrate 12 is a resin substrate made of a resin material, such as polyimide, so that the display device 1 is a flexible display device. For the display device 1 to be a non-flexible display device, the substrate 12 can be a glass substrate.

The barrier layer 3 is a layer that prevents foreign substances, such as water and oxygen, from entering the transistors TR, and light-emitting elements of individual colors, which will be described later on, and the barrier layer 3 can be composed of, for instance, a silicon oxide film, a silicon nitride film, or a silicon oxide nitride film, all of which are formed through chemical vapor deposition (CVD), or can be composed of, for instance, a laminate of these films.

A transistor-TR portion of the thin-film transistor layer 4 including the transistors TR includes the following: a semiconductor film SEM, and doped semiconductor films SEM′ and SEM″; an inorganic insulating film 16; a gate electrode G; an inorganic insulating film 18; an inorganic insulating film 20; a source electrode S and a drain electrode D; and a flattening film 21, and a portion excluding the transistor-TR portion of the thin-film transistor layer 4 including the transistors TR includes the inorganic insulating film 16, the inorganic insulating film 18, the inorganic insulating film 20, and the flattening film 21.

The semiconductor films SEM, SEM′, and SEM″ may be composed of, for instance, low-temperature polysilicon (LTPS), or an oxide semiconductor (e.g., an In—Ga—Zn—O semiconductor). Although this embodiment describes, by way of example, an instance where the transistors TR are of top-gate structure, the transistors TR may be of bottom-gate structure.

The gate electrode G, the source electrode S, and the drain electrode D can be composed of, for instance, a metal monolayer film or metal laminated film containing at least one of aluminum, tungsten, molybdenum, tantalum, chromium, titanium, and copper.

The inorganic insulating film 16, the inorganic insulating film 18, and the inorganic insulating film 20 can be composed of, for instance, a silicon oxide film, a silicon nitride film, or a silicon oxide nitride film, all of which are formed through chemical vapor deposition (CVD), or can be composed of, for instance, a laminate of these films.

The flattening film 21 can be composed of, for instance, an organic material that can be applied, such as polyimide or acrylic.

As illustrated in FIG. 2, a control circuit including the transistor TR, that controls a corresponding one of the plurality of first electrodes 22 is provided in the thin-film transistor layer 4 including the transistors TR.

FIG. 3 is a sectional view of a schematic configuration of a red light-emitting element 30R, of a green light-emitting element 30G, and of a blue light-emitting element 30B all of which are included in the display device 1 according to the first embodiment.

The red light-emitting element 30R is provided in the red subpixel RSP illustrated in FIG. 1, the green light-emitting element 30G is provided in the green subpixel GSP illustrated in FIG. 1, and the blue light-emitting element 30B is provided in the blue subpixel BSP illustrated in FIG. 1.

As illustrated in FIG. 3, the red light-emitting element 30R includes the first electrode 22, a hole transport layer 23, a red light-emitting layer 25R, an electron transport layer 26, and a second electrode 27 in the stated order on the substrate 2 including the transistors TR. The green light-emitting element 30G includes the first electrode 22, the hole transport layer 23, a green light-emitting layer 25G, the electron transport layer 26, and the second electrode 27 in the stated order on the substrate 2 including the transistors TR. The blue light-emitting element 30B includes the first electrode 22, the hole transport layer 23, a blue light-emitting layer 25B, the electron transport layer 26, and the second electrode 27 in the stated order on the substrate 2 including the transistors TR.

Although the red light-emitting element 30R, green light-emitting element 30G, and blue light-emitting element 30B illustrated in FIG. 3 are described, by way of example, as being of forward stacked structure with the first electrode 22 being an anode, and with the second electrode 27 being a cathode, these elements may be of inverted stacked structure, as described later on, with the first electrode 22 being a cathode, and with the second electrode 27 being an anode.

When the red light-emitting element 30R, green light-emitting element 30G, and blue light-emitting element 30B illustrated in FIG. 3 are of forward stacked structure, a top-emission light-emitting element can be achieved by forming the first electrode 22, which is an anode, with an electrode material that reflects visible light, and by forming the second electrode 27, which is a cathode, with an electrode material that transmits visible light.

The electrode material that reflects visible light may be any material that can reflect visible light, and that is conductive; usable examples include, but not limited to, a metal material, such as Al, Mg, Li or Ag, an alloy of the metal material, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light, and that is conductive; usable examples include a transparent metal oxide (e.g., an indium tin oxide, an indium zinc oxide, and an indium gallium zinc oxide), a thin film made of a metal material, such as Al, Mg, Li or Ag, and a conductive nano material, such as silver nanowires or carbon nanotubes.

As illustrated in FIG. 3, a self-assembled monolayer 24, the red light-emitting layer 25R, the green light-emitting layer 25G, and the blue light-emitting layer 25B are provided on the hole transport layer 23 of the display device 1.

Although this embodiment describes, by way of example, an instance where an underlayer having a polar surface on which the self-assembled monolayer 24 is formed is the hole transport layer 23, the underlayer on which the self-assembled monolayer 24 is formed may be, as described later on, for instance, the electron transport layer 26, or the substrate 2 including the transistors TR, as well as the first electrode 22 or a first electrode 22a. It is noted that the underlayer on which the self-assembled monolayer 24 is formed can be made of a material with which a self-assembled monomolecule 5 can coordinate, and that contains, for instance, metal or Si atoms; examples include a metal oxide and a metal sulfide. When the underlayer with which the self-assembled monomolecule 5 can coordinate is a hole transport layer, the hole transport layer can be made of NiO for instance, when the underlayer with which the self-assembled monomolecule 5 can coordinate is an electron transport layer, the electron transport layer can be made of ZnO for instance, and when the underlayer with which the self-assembled monomolecule 5 can coordinate is an insulating layer, the insulating layer can be made of Al₂O₃, SiO₂, or other materials.

Although this embodiment describes the hole transport layer 23 made of NiO, a hole transport layer made of metal chalcogenide can be used suitably. A distal end FG2 on the other side of the self-assembled monomolecule 5, which will be described later on, coordinates with a metal cation (Ni⁺) of the hole transport layer 23.

As described above, the underlayer preferably has a polar surface and more desirably has a hydrophilic surface.

As denoted by A in FIG. 3, the self-assembled monolayer 24, whose surface is non-polar, is a monomolecular film composed of monomolecules adjacent to each other, each of which has a distal end FG1 on one side that is a non-polar functional group, and having a non-polar surface, and the self-assembled monolayer 24 is composed of the self-assembled monomolecule 5 whose distal end FG1 on one side is a non-polar functional group. It is noted that the non-polar functional group is preferably CH₃ or CF₃ for instance, because such a non-polar functional group can increase liquid repellency against a polar solvent in particular. An example of the self-assembled monomolecule 5 whose distal end FG1 on one side is CH₃ is hexamethyldisilazane (HMDS).

It is noted that the self-assembled monomolecule 5 illustrated in FIG. 3 preferably has a functional group that can typically coordinate with a cation at the distal end FG2 on the other side. To be specific, a possible instance is that the functional group includes any one or more of a thiol group, an alkoxyl group, a carboxyl group, a phosphonate group, and a phosphinic acid group. An ionized self-assembled monomolecule containing one or more thiol groups at its distal end partly includes a structure expressed by Structural Formula (1) or Structural Formula (2) below. An ionized self-assembled monomolecule containing an alkoxyl group at its distal end partly includes a structure expressed by Structural Formula (3) below. An ionized self-assembled monomolecule containing a carboxyl group at its distal end partly includes a structure expressed by Structural Formula (4) below. An ionized self-assembled monomolecule containing a phosphonate group at its distal end partly includes a structure expressed by Structural Formula (5) or Structural Formula (6) below. An ionized self-assembled monomolecule containing a phosphinic acid group at its distal end partly includes a structure expressed by Structural Formula (7) below.

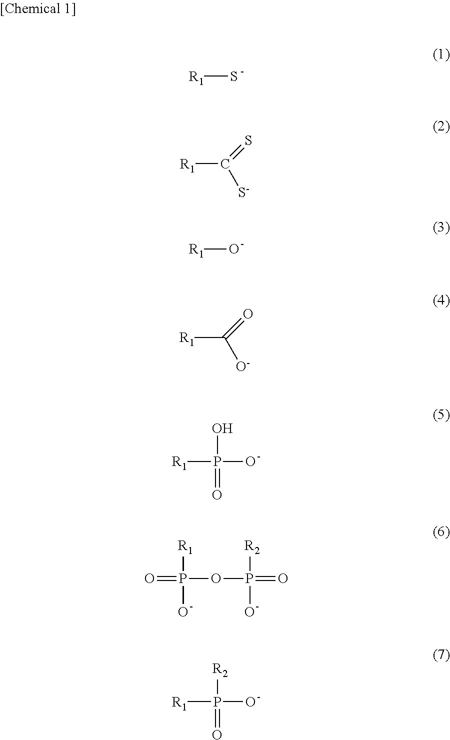

It is noted that in Structural Formulas (1) to (7) above, C denotes a carbon atom, O denotes an oxygen atom, O-denotes an oxide ion, S denotes a sulfur atom, S-denotes a sulfide ion, P denotes a phosphorus atom, and R₁ and R₂ denote a hydrogen atom, an alkyl group, an aryl group, an alkoxyl group, or an unsaturated hydrocarbon group independently of each other.

Further, a possible specific instance other than the foregoing instances is that the functional group includes one or more phosphine groups, phosphine oxide groups, and amine groups at its distal end. A self-assembled monomolecule containing a phosphine group at its distal end partly includes a structure expressed by Structural Formula (8) or Structural Formula (9) below. A self-assembled monomolecule containing a phosphine oxide group at its distal end partly includes a structure expressed by Structural Formula (10) below. A self-assembled monomolecule containing an amine group at its distal end partly includes a structure expressed by any one of Structural Formulas (11) to (15) below.

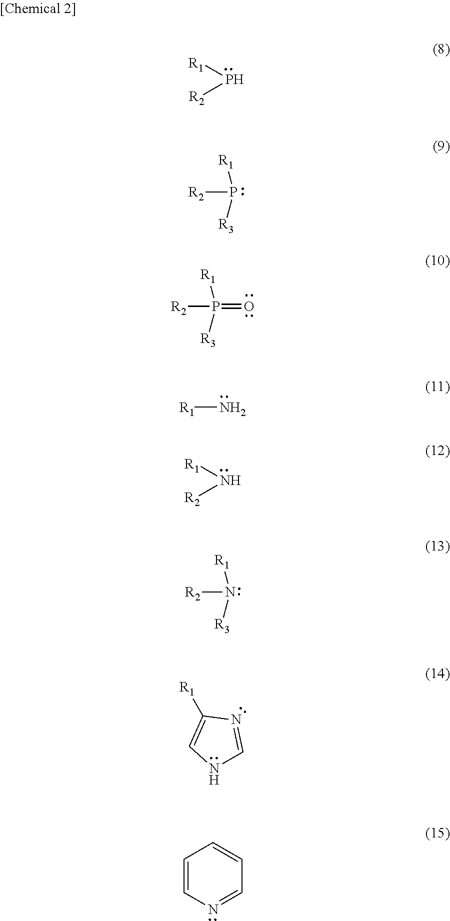

It is noted that in Structural Formulas (8) to (15) above, H denotes a hydrogen atom, N denotes a nitrogen atom, O denotes an oxygen atom, P denotes a phosphorus atom, and R₁, R₂, and R₃ denote a hydrogen atom, an alkyl group, an aryl group, an alkoxyl group, or an unsaturated hydrocarbon group independently of each other.

However, the functional group is not limited to the foregoing examples; another functional group having a commonly known capability to coordinate with a cation may be used.

As described above, the self-assembled monolayer 24 preferably has a non-polar surface and more desirably has a hydrophobic surface.

The display device 1, which includes the self-assembled monolayer 24 composed of the self-assembled monomolecule 5 having high liquid repellency against a polar solvent, and whose surface is liquid-repellent, that is, water-repellent against a polar solvent, can prevent deterioration that results from moisture entrance into the red light-emitting layer 25R, green light-emitting layer 25G, and blue light-emitting layer 25B thanks to the water-repellent surface of the self-assembled monolayer 24.

Further, the self-assembled monomolecule 5 preferably contains, at the distal end FG2 on the other side, any of a thiol group, an alkoxyl group, a carboxyl group, a phosphonate group, a phosphinic acid group, and organic silane (R′ₙSiX₄₋ₙ, where n is equal to one, two, or three, where X is Cl or an OR group, where R and R′ are an alkyl group). Such a self-assembled monomolecule 5 can be strongly bonded with an underlayer film made of an inorganic material.

When the self-assembled monomolecule 5 contains alkoxysilane at the distal end FG2 on the other side, the distal ends FG2 on the other sides of the self-assembled monomolecules 5 cross-link, thus increasing the elaborateness and stability of the self-assembled monolayer 24, thus enhancing liquid repellency against a polar solvent.

Further, when the self-assembled monomolecule 5 contains a phosphonate group at the distal end FG2 on the other side, forming an inorganic matrix IOM, which will be described later on and is included in each of the red light-emitting layer 25G, green light-emitting layer 25G, and blue light-emitting layer 25B, by the use of a metal oxide promotes coordination of the self-assembled monomolecule 5 with the inorganic matrix IOM in a chain-reaction manner and can thus enhance the elaborateness of the self-assembled monomolecule 5 that is formed on the surface of the inorganic matrix IOM.

Further, when the self-assembled monomolecule 5 contains organic silane at the distal end FG2 on the other side, forming the inorganic matrix IOM, which will be described later on and is included in each of the red light-emitting layer 25G, green light-emitting layer 25G, and blue light-emitting layer 25B, by the use of a silicon oxide is preferable, because the self-assembled monomolecule 5 establishes firm siloxane bonding (—Si—O—Si—) with such an inorganic matrix IOM.

It is noted that a functional group being typically capable of coordinating with a cation, and contained in a monomolecule whose distal end FG1 on one side is a non-polar functional group, that is, the self-assembled monomolecule 5 whose distal end FG1 on one side is a non-polar functional group is divided into the following types when the functional group coordinates or bonds with an underlayer film: one is a functional group that involves no change in its molecular configuration; and the other is a functional group that involves a change in its molecular configuration, like hexamethyldisilazane (HMDS) for instance.

Further, the self-assembled monomolecule 5 preferably includes C—C bonding or Si—O bonding at relatively low bonding energy between the distal end FG1 on one side and the distal end FG2 on the other side. Such a self-assembled monomolecule 5 can be easily decomposed by light; hence, using such a self-assembled monomolecule 5 enables an exposure step, which will be described later on, to be performed with light of relatively low energy and can thus prevent undesirable deterioration in a light-emitting material. It is noted that with regard to the decomposition by light, supplying energy exceeding C—C bonding energy (347.7 KJ/mol) or Si—O bonding energy (369.0 KJ/mol) disconnects the bonding, and the decomposition can be done by reaction with surrounding oxygen. This can be easily achieved by the use of, for instance, a low-pressure mercury lamp (472 KJ/mol) having a wavelength of 254 mm.

Further, although not illustrated, the self-assembled monomolecule 5 preferably includes a carbon chain composed of 15 or more carbon atoms in its main chain. Forming the self-assembled monolayer 24 by the use of the self-assembled monomolecule 5 including a carbon chain composed of 15 or more carbon atoms in its main chain offers a relatively large angle of contact with a polar solvent on the layer's surface; accordingly, the self-assembled monolayer 24 having higher liquid repellency against the polar solvent can be formed.

The red light-emitting layer 25R illustrated in FIG. 3 includes quantum dots QD1 embedded in the inorganic matrix IOM, the green light-emitting layer 25G illustrated in FIG. 3 includes quantum dots QD2 embedded in the inorganic matrix IOM, and the blue light-emitting layer 25B illustrated in FIG. 3 includes quantum dots QD3 embedded in the inorganic matrix IOM.

Here, a light-emitting layer including quantum dots embedded in an inorganic matrix means not only an instance where all the quantum dots included in the light-emitting layer are embedded in the inorganic matrix, but also an instance where only some of the quantum dots included in the light-emitting layer are embedded in the inorganic matrix. Further, that a quantum dot is embedded in an inorganic matrix means not only an instance where a single quantum dot is entirely covered with the inorganic matrix, but also an instance where only part of a single quantum dot is covered with the inorganic matrix. This embodiment describes, by way of example, an instance—this is desirable because damage on quantum dots can be reduced further—where all the quantum dots included in a light-emitting layer are embedded in an inorganic matrix, and where each quantum dot is entirely covered with the inorganic matrix.

It is noted that a quantum dot means a dot having a maximum width of 100 nm or smaller. The quantum dot has any shape that satisfies this maximum width; the shape is not limited to a spherical tridimensional shape (circular cross-section shape). For instance, the quantum dot may have a polygonal cross-section shape, a bar-shaped tridimensional shape, a branch-shaped tridimensional shape, a tridimensional shape having surface asperities, or a combination of them.

Further, an inorganic material means a member made of an inorganic material, and containing and retaining another substance. That is, an inorganic material herein is a member made of an inorganic material, and containing and retaining quantum dots.

As described above, the display device 1, which includes the red light-emitting layer 25R including the quantum dots QD1 embedded in the inorganic matrix IOM, the green light-emitting layer 25G including the quantum dots QD2 embedded in the inorganic matrix IOM, and the blue light-emitting layer 25B including the quantum dots QD3 embedded in the inorganic matrix IOM, can reduce damage on the quantum dots QD1, quantum dots QD2, and quantum dots QD3.

The emission peak wavelength of the quantum dots QD1 is longer than the emission peak wavelength of the quantum dots QD2, and the emission peak wavelength of the quantum dots QD2 is longer than the emission peak wavelength of the quantum dots QD3. In this embodiment, the quantum dots QD1 are quantum dots that emit red, the quantum dots QD2 are quantum dots that emit green, and the quantum dots QD3 are quantum dots that emit blue.

The quantum dots QD1, the quantum dots QD2, and the quantum dots QD3 preferably contain one or more semiconductor materials selected from the group including Cd, S, Te, Se, Zn, In, N, P, As, Sb, Al, Ga, Pb, Si, Ge, Mg, and their compounds. For instance, the quantum dots QD1, the quantum dots QD2, and the quantum dots QD3 can be formed by the use of a material containing one or more selected from the group consisting of CdS, CdSe, CdTe, ZnS, ZnSe, ZnTe, ZnO, HgS, HgSe, HgTe, CdSeS, CdSe Te, CdSTe, ZnSeS, ZnSeTe, ZnSTe, HgSe, HgSeTe, HgSTe, CdZnS, CdZnSe, CdZnTe, CdHgS, CdHgSe, CdHgTe, HgZnS, HgZnSe, CdHgTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, and SiGe.

In this embodiment, quantum dots of different materials are used, by way of example, in order for the quantum dots QD1, the quantum dots QD2, and the quantum dots QD3 to emit different colors. Quantum dots of the same material having different particle diameters may be used in order for the quantum dots QD1, the quantum dots QD2, and the quantum dots QD3 to emit different colors. For instance, a quantum dot having the largest particle diameter can be used as a red-emitting quantum dot, a quantum dot having the smallest particle diameter can be used as a blue-emitting quantum dot, and a quantum dot having a particle diameter falling between the particle diameter of the quantum dot used as the red-emitting quantum dot and the particle diameter of the quantum dot used as the blue-emitting quantum dot can be used as a green-emitting quantum dot.

The quantum dots QD1, the quantum dots QD2, and the quantum dots QD3 desirably include, on their surfaces, such ligands as to be able to be dispersed in a polar solvent, which will be described later on. A non-limiting example is an inorganic ligand.

Although this embodiment describes, by way of example, an instance where the red light-emitting layer 25R, the green light-emitting layer 25G, and the blue light-emitting layer 25B individually include the same inorganic matrix IOM, the red light-emitting layer 25R, the green light-emitting layer 25G, and the blue light-emitting layer 25B may individually include different inorganic matrixes, as described later on.

The inorganic material IOM can be formed from an inorganic material precursor in a solution process using a polar solvent, which will be described later on.

The inorganic matrix IOM is preferably configured such that the valence band maximum (VBM) of the inorganic matrix IOM is deeper than the valence band maximum (VBM) of each of the quantum dots QD1, quantum dots QD2, and quantum dots QD3, and such that the conduction band minimum (CBM) of the inorganic matrix IOM is shallower than the conduction band minimum (CBM) of each of the quantum dots QD1, quantum dots QD2, and quantum dots QD3. Such a configuration can prevent an excess voltage rise and can avoid the electrons and holes within the quantum dots from moving to the inorganic matrix IOM. It is noted that “the VBM of the inorganic matrix IOM is deeper than the VBM of the quantum dots” is equal in meaning to “the ionization energy of the inorganic matrix IOM (that is, the absolute value of the difference between a vacuum level and the VBM) is larger than the ionization energy of the quantum dots”. It is also noted that “the CBM of the inorganic matrix IOM is shallower than the CBM of the quantum dots” is equal in meaning to “the electron affinity of the inorganic matrix IOM (that is, the absolute value of the difference between a vacuum level and the CBM) is smaller than the electron affinity of the quantum dots”.

The inorganic matrix IOM is preferably an insulating one in order to prevent current leakage.

Although this embodiment describes, by way of example, an instance where the inorganic material IOM made of Al₂O₃ is formed using (Al(NO₃)₃) as an inorganic material precursor, the inorganic material IOM may be made of metal oxide other than Al₂O₃. For the inorganic matrix IOM made of metal oxide, the self-assembled monolayer 24 that is more elaborate can be formed onto the surface of the inorganic matrix IOM. Accordingly, the self-assembled monolayer 24 with higher liquid-repellency against a polar solvent can reduce a defect and a color mixture in a light-emitting layer.

The inorganic matrix IOM may be an oxide containing one or more of Ti, Nb, Al, Si, Mg, Ta, Hf, Zr, Y, La, and Sr, or the inorganic matrix IOM may be a sulfide containing one or more of Zn, Ti, Nb, Al, Si, Mg, Ta, Hf, Zr, Y, La, and Sr. Such a configuration can achieve a display device provided with the following: the layer-emitting layer 25R including the quantum dots QD1 embedded in an inorganic hole transport layer, an inorganic electron transport layer, an inorganic carrier-blocking layer, or other layers all composed of a metal chalcogenide; the green light-emitting layer 25G including the quantum dots QD2 embedded in the foregoing; and the blue light-emitting layer 25B including the quantum dots QD3 embedded in the foregoing.

It is noted that one including a set of stable crystal planes with the difference in lattice constant being small enough to enable epitaxial growth on a material contained in the surface of a quantum dot is more desirably selected as the material of the inorganic matrix IOM. Such a configuration can reduce the density of defects at the interface between the surfaces of the quantum dots and the inorganic matrix IOM. For instance, for a quantum dot containing ZnS in its surface, it is preferable to use a material containing yttrium oxide (e.g., Y₂O₃) as the material of the inorganic matrix IOM. In this case, the difference in lattice constant between the ZnS (100) plane of the quantum dot and the Y₂O₃ (100) plane stands at about 2%, and thus, the Y₂O₃ (100) plane can undergo epitaxial growth on the ZnS (100) plane. In process steps of forming light-emitting layers, which will be described later on, a light-emitting layer including quantum dots embedded in an inorganic matrix containing yttrium oxide can be formed by epitaxially growing the Y₂O₃ from the ZnS. Although the foregoing has described, by way of example, an instance where the material contained in the surfaces of the quantum dots and the material of the inorganic matrix IOM are different, the material of the inorganic matrix IOM may undergo epitaxial growth from the surfaces of the quantum dots by the use of the same material between the material contained in the surfaces of the quantum dots and the material of the inorganic matrix IOM.

For instance, the inorganic material IOM made of ZnS, which is a metal sulfide, can be formed in a solution process using an inorganic material precursor, and the inorganic material IOM made of ZnS, which has relatively large band gap (high insulation), is preferable. MgS, which is a metal sulfide, and other substances are also suitable materials for a similar reason.

The inorganic matrix IOM is preferably amorphous. An amorphous material has many points of reaction with the self-assembled monomolecule 5 because dangling bonds of a constituent atom tend to be left due to structural disarray, thus facilitating formation of the self-assembled monomolecule 5 that is elaborate onto the surface of the inorganic matrix IOM. This improves liquid repellency against a polar solvent, thus achieving further yield enhancement, and further prevention of a color mixture. An amorphous inorganic material, for instance, amorphous Al₂O₃, is obtained by melting an aluminum nitrate hydrate that is an inorganic material precursor into dimethyl sulfoxide (DMSO), ethanol, or other things, followed by heating at a temperature of about 200 to 600° C. inclusive. As a better heating condition, about 30-minute heating at 200 to 300° C. inclusive is preferable. This is because that an excessively long heating time or an excessively high heating temperature causes atoms to be re-arranged to thus promote crystallization.

As illustrated in FIG. 3, the self-assembled monolayer 24 is preferably formed except on the upper surface of the red light-emitting layer 25R, the upper surface of the green light-emitting layer 25G, and the upper surface of the blue light-emitting layer 25B. Such a configuration offers wide selection of materials for a layer that is to be formed directly on the light-emitting layer of each color, because no self-assembled monolayer 24 having liquid repellency against a polar solvent is formed on the upper surface of the red light-emitting layer 25R, the upper surface of the green light-emitting layer 25G, and the upper surface of the blue light-emitting layer 25B.

Although this embodiment describes, by way of example, an instance where the electron transport layer 26 illustrated in FIG. 3 is made of ZnO, the electron transport layer 26 may be made of, for instance, a metal oxide other than ZnO, or an organic material.

The foregoing display device 1 illustrated in FIG. 3, which is provided with the red light-emitting layer 25R including the quantum dots QD1 embedded in the inorganic matrix IOM, the green light-emitting layer 25G including the quantum dots QD2 embedded in the inorganic matrix IOM, and the blue light-emitting layer 25B including the quantum dots QD3 embedded in the inorganic matrix IOM, can reduce damage on the quantum dots QD1, quantum dots QD2, and quantum dots QD3 in a process of forming each layer. In addition, the self-assembled monolayer 24, which has a surface that exhibits liquid repellency against a polar solvent, can prevent deterioration that results from moisture entrance into the red light-emitting layer 25R, green light-emitting layer 25G, and blue light-emitting layer 25B. In addition, the self-assembled monolayer 24, when formed on the red light-emitting layer 25R, green light-emitting layer 25G, and blue light-emitting layer 25B, can prevent a defect in the red light-emitting layer 25R, green light-emitting layer 25G, and blue light-emitting layer 25B and can prevent deterioration that results from water entrance from the electron transport layer 26.

Although this embodiment describes, by way of example, an instance where the red light-emitting layer 25R, the green light-emitting layer 25G, and the blue light-emitting layer 25B all include the inorganic matrix IOM, only one or two of the red light-emitting layer 25R, green light-emitting layer 25G, and blue light-emitting layer 25B may include the inorganic matrix IOM.

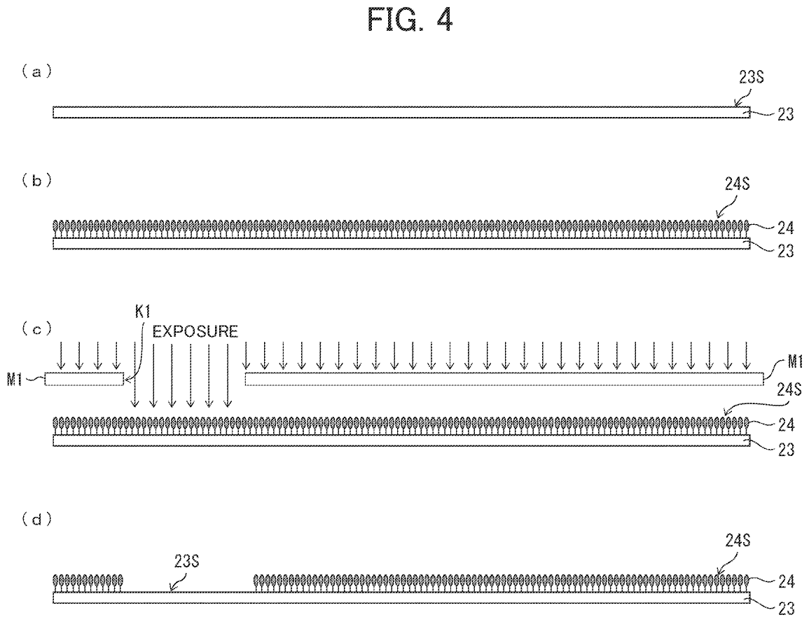

FIG. 4(a), FIG. 4(b), FIG. 4(c), and FIG. 4(d) illustrate some of process steps for manufacturing the display device 1 according to the first embodiment.

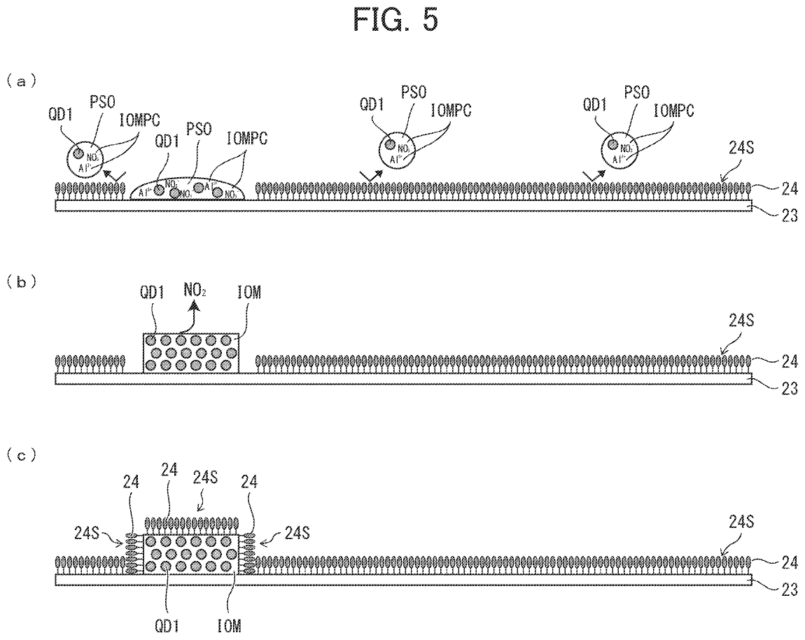

FIG. 5(a), FIG. 5(b), and FIG. 5(c) illustrate some of the process steps for manufacturing the display device 1 according to the first embodiment that are performed after the process step illustrated in FIG. 4(d).

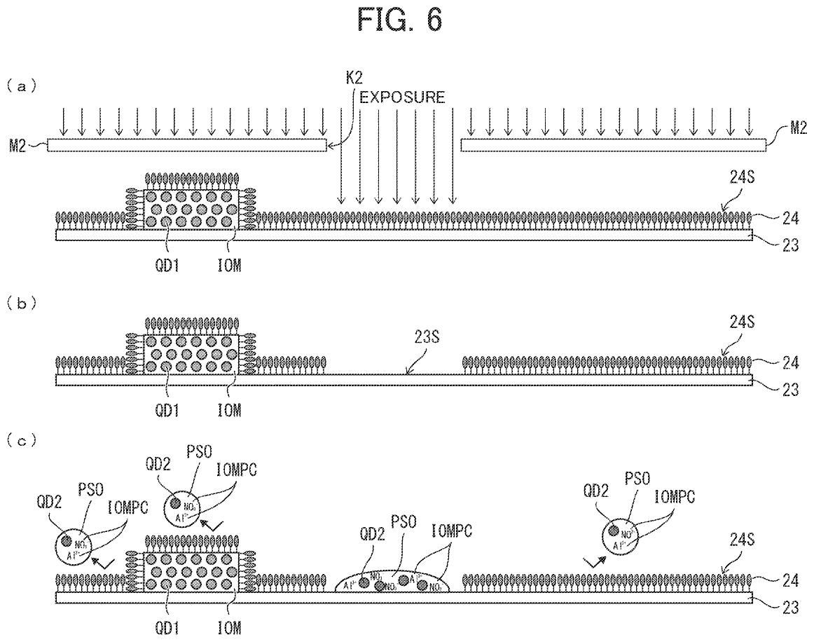

FIG. 6(a), FIG. 6(b), and FIG. 6(c) illustrate some of the process steps for manufacturing the display device according to the first embodiment that are performed after the process step illustrated in FIG. 5(c).

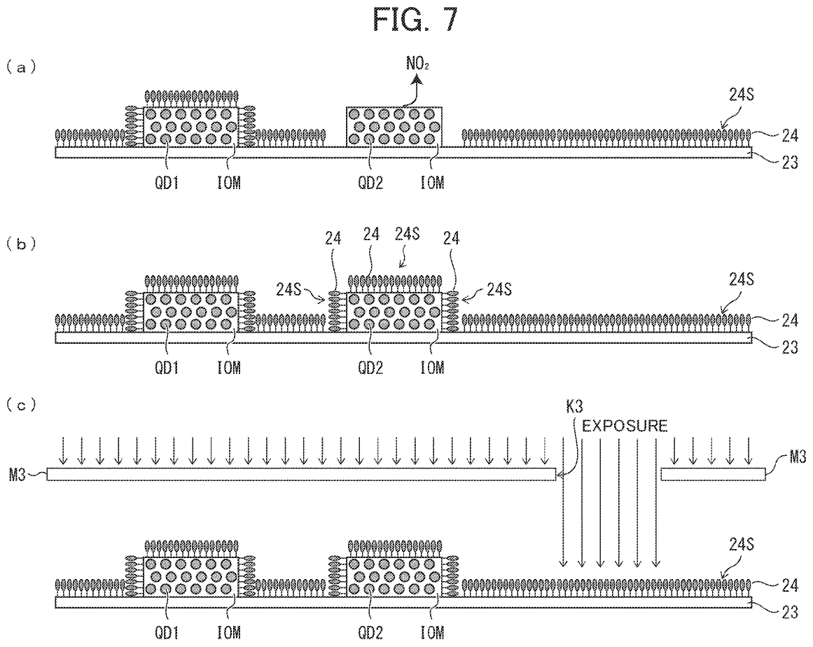

FIG. 7(a), FIG. 7(b), and FIG. 7(c) illustrate some of the process steps for manufacturing the display device according to the first embodiment that are performed after the process step illustrated in FIG. 6(c).

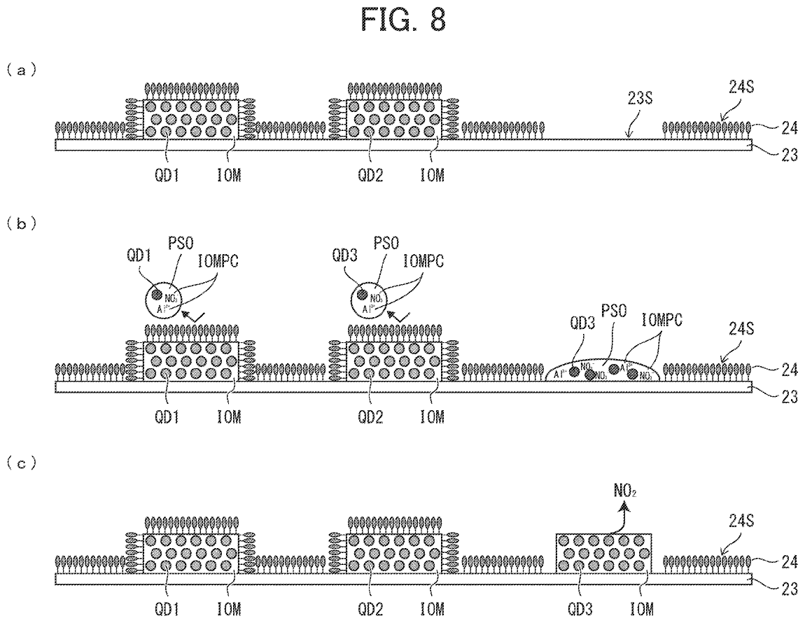

FIG. 8(a), FIG. 8(b), and FIG. 8(c) illustrate some of the process steps for manufacturing the display device according to the first embodiment that are performed after the process step illustrated in FIG. 7(c).

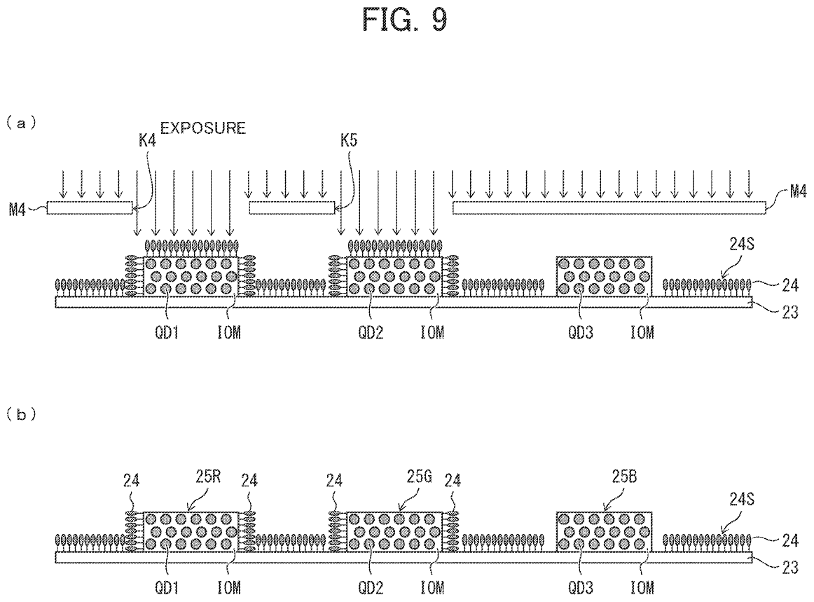

FIG. 9(a) and FIG. 9(b) illustrate some of the process steps for manufacturing the display device according to the first embodiment that are performed after the process step illustrated in FIG. 8(c).

As illustrated in FIG. 4, the hole transport layer 23, which is made of NiO and is an underlayer on which the self-assembled monolayer 24 is to be formed, has a polar surface 23. In a process step of forming a non-polar region illustrated in FIG. 4(b), the self-assembled monolayer 24 is formed onto the polar surface 23S of the hole transport layer 23 by the use of the self-assembled monomolecule 5 whose distal end FG1 on one of its sides is a non-polar functional group, to form the non-polar region, which is a surface 24S of the self-assembled monolayer 24. Here, the non-polar region is a region that exhibits liquid repellency against a polar solvent, and to be more specific, the non-polar region means a region having a greater than 90° angle of contact with water. In a process step of forming a first polar surface region illustrated in FIG. 4(c) and FIG. 4(d), a region in which the first polar surface region is to be formed undergoes light irradiation via a mask M1 having an opening K1, to remove a part of the self-assembled monolayer 24 to thus form the first polar surface region, which is the polar surface 23S of the hole transport layer 23. Here, the first polar surface region is a region that exhibits no liquid repellency against a polar solvent, and to be more specific, the first polar surface region means a region having a 90° or smaller angle of contact with water. In this process step, light irradiation by the use of, for instance, a low-pressure mercury lamp (472 KJ/mol) having a wavelength of 254 nm is performed to disconnect part of the bonding between the self-assembled monomolecules 5, constituting the self-assembled monolayer 24, to cause the self-assembled monomolecules 5 to react with surrounding oxygen, so that the self-assembled monomolecules 5 can be decomposed and removed. Accordingly, additional process steps, such as development and rinse, do not have to be performed.

Next, in a process step of forming a quantum-dot-QD1 application solution illustrated in FIG. 5(a), the quantum-dot-QD1 application solution containing the quantum dots QD1, inorganic material precursors IOMPC, and a polar solvent PSO is selectively formed in the first polar surface region. In this embodiment, Al(NO₃)₃ is used as the inorganic material precursors IOMPC. In addition, although DMSO is used as the polar solvent PSO by way of example, a polar solvent having a relative permittivity of 10 or greater can be used for instance, and a polar solvent having a relative permittivity of 30 or greater can be used suitably for instance. The quantum-dot-QD1 application solution, with the quantum dots QD1 and inorganic material precursors IOMPC dispersed in the polar solvent PSO, is rejected in the non-polar region, which is the surface 24S of the self-assembled monolayer 24, and is selectively formed in only the first polar surface region, which is the polar surface 23S of the hole transport layer 23. In a process step of forming the red light-emitting layer 25R illustrated in FIG. 5(b), which is performed after the process step of forming the quantum-dot-QD1 application solution illustrated in FIG. 5(a), at least one of heating and light irradiation is performed to form the red light-emitting layer 25R including the quantum dots QD1 embedded in the inorganic matrix IOM composed of the inorganic material precursors IOMPC. It is noted that 30-minute heating at 200 to 300° C. inclusive is performed in this embodiment by way of example, in order to form amorphous Al₂O₃ as the inorganic matrix IOM. After the process step of forming the red light-emitting layer 25R illustrated in FIG. 5(b), the self-assembled monolayer 24 is formed onto at least the surface of the inorganic matrix IOM by the use of the self-assembled monomolecules 5, as illustrated in FIG. 5(c). As illustrated in FIG. 5(c), the self-assembled monolayer 24 is formed onto the side surface and upper surface of the inorganic matrix IOM except the lower surface of the inorganic matrix IOM, which is in contact with the hole transport layer 23. It is noted that although the self-assembled monomolecules 5 can be decomposed and removed through the heating in the process step of forming the red light-emitting layer 25R illustrated in FIG. 5(b), the removed self-assembled monolayer 24 can be repaired by forming the self-assembled monolayer 24 onto the entire surface in the process step illustrated in FIG. 5(c).

Next, in a process step of forming a second polar surface region illustrated in FIG. 6(a) and FIG. 6(b), a region in which the second polar surface region is to be formed undergoes light irradiation via a mask M2 having an opening K2, to remove another part of the self-assembled monolayer 24 different from the first polar surface region, to thus form the second polar surface region, which is the polar surface 23S of the hole transport layer 23. Here, the second polar surface region is a region that exhibits no liquid repellency against a polar solvent, and to be more specific, the second polar surface region means a region having a 90° or smaller angle of contact with water. In this process step, light irradiation by the use of, for instance, a low-pressure mercury lamp (472 KJ/mol) having a wavelength of 254 nm is performed to disconnect part of the bonding between the self-assembled monomolecules 5, constituting the self-assembled monolayer 24, to cause the self-assembled monomolecules 5 to react with surrounding oxygen, so that the self-assembled monomolecules 5 can be decomposed and removed. Accordingly, additional process steps, such as development and rinse, do not have to be performed. In a process step of forming a quantum-dot-QD2 application solution illustrated in FIG. 6(c), the quantum-dot-QD2 application solution containing the quantum dots QD2, the inorganic material precursors IOMPC, and the polar solvent PSO is selectively formed in the second polar surface region. The quantum-dot-QD2 application solution, with the quantum dots QD2 and inorganic material precursors IOMPC dispersed in the polar solvent PSO, is rejected in the non-polar region, which is the surface 24S of the self-assembled monolayer 24, and is selectively formed in only the second polar surface region, which is the polar surface 23S of the hole transport layer 23. In a process step of forming the green light-emitting layer 25G illustrated in FIG. 7(a), which is performed after the process step of forming the quantum-dot-QD2 application solution illustrated in FIG. 6(c), at least one of heating and light irradiation is performed to form the green light-emitting layer 25G including the quantum dots QD2 embedded in the inorganic matrix IOM composed of the inorganic material precursors IOMPC. It is noted that 30-minute heating at 200 to 300° C. inclusive is performed in this embodiment by way of example, in order to form amorphous Al₂O₃ as the inorganic matrix IOM. After the process step of forming the green light-emitting layer 25G illustrated in FIG. 7(a), the self-assembled monolayer 24 is formed onto at least the surface of the inorganic matrix IOM by the use of the self-assembled monomolecule 5, as illustrated in FIG. 7(b). As illustrated in FIG. 7(b), the self-assembled monolayer 24 is formed onto the side surface and upper surface of the inorganic matrix IOM except the lower surface of the inorganic matrix IOM, which is in contact with the hole transport layer 23. It is noted that although the self-assembled monomolecules 5 can be decomposed and removed through the heating in the process step of forming the green light-emitting layer 25G illustrated in FIG. 7(a), the removed self-assembled monolayer 24 can be repaired by forming the self-assembled monolayer 24 onto the entire surface in the process step illustrated in FIG. 7(b).

Next, in a process step of forming a third polar surface region illustrated in FIG. 7(c) and FIG. 8(a), a region in which the third polar surface region is to be formed undergoes light irradiation via a mask M3 having an opening K3, to remove further another part of the self-assembled monolayer 24 different from the first polar surface region and second polar surface region, to thus form the third polar surface region, which is the polar surface 23S of the hole transport layer 23. Here, the third polar surface region is a region that exhibits no liquid repellency against a polar solvent, and to be more specific, the third polar surface region means a region having a 90° or smaller angle of contact with water. In this process step, light irradiation by the use of, for instance, a low-pressure mercury lamp (472 KJ/mol) having a wavelength of 254 nm is performed to disconnect part of the bonding between the self-assembled monomolecules 5, constituting the self-assembled monolayer 24, to cause the self-assembled monomolecules 5 to react with surrounding oxygen, so that the self-assembled monomolecules 5 can be decomposed and removed. Accordingly, additional process steps, such as development and rinse, do not have to be performed. In a process step of forming a quantum-dot-QD3 application solution illustrated in FIG. 8(b), the quantum-dot-QD3 application solution containing the quantum dots QD3, the inorganic material precursors IOMPC, and the polar solvent PSO is selectively formed in the third polar surface region. The quantum-dot-QD3 application solution, with the quantum dots QD3 and inorganic material precursors IOMPC dispersed in the polar solvent PSO, is rejected in the non-polar region, which is the surface 24S of the self-assembled monolayer 24, and is selectively formed in only the third polar surface region, which is the polar surface 23S of the hole transport layer 23. In a process step of forming the blue light-emitting layer 25B illustrated in FIG. 8(c), which is performed after the process step of forming the quantum-dot-QD3 application solution illustrated in FIG. 8(b), at least one of heating and light irradiation is performed to form the blue light-emitting layer 25B including the quantum dots QD3 embedded in the inorganic matrix IOM composed of the inorganic material precursors IOMPC. It is noted that 30-minute heating at 200 to 300° C. inclusive is performed in this embodiment by way of example, in order to form amorphous Al₂O₃ as the inorganic matrix IOM.

Although the self-assembled monolayer 24 is not formed on the surface of the inorganic matrix IOM included in the blue light-emitting layer 25B, which is a light-emitting layer that is formed the last, by the use of the self-assembled monomolecule 5 in this embodiment by way of example, the self-assembled monolayer 24 may be formed also onto the surface of the inorganic matrix IOM included in the blue light-emitting layer 25B, which is a light-emitting layer that is formed the last, by the use of the self-assembled monomolecule 5. As described above, the self-assembled monolayer 24 that is formed onto the surface of the inorganic matrix IOM by the use of the self-assembled monomolecule 5 can reduce a defect and a color mixture in a light-emitting layer. In addition, the non-polar (water-repellent) surface 24S of the self-assembled monolayer 24 can further prevent deterioration that results from moisture entrance into the light-emitting layer.

In this embodiment, the self-assembled monolayer 24 is not formed on the surface of the inorganic matrix IOM included in the blue light-emitting layer 25B, which is a light-emitting layer that is formed the last, by the use of the self-assembled monomolecule 5, as earlier described. Moreover, as illustrated in FIG. 9(a) and FIG. 9(b), the self-assembled monolayer 24 formed on the upper surface of the inorganic matrix IOM included in the red light-emitting layer 25R, and the self-assembled monolayer 24 formed on the upper surface of the inorganic matrix IOM included in the green light-emitting layer 25G undergo light irradiation via a mask M4 having an opening K4, corresponding to the upper surface of the inorganic matrix IOM included in the red light-emitting layer 25R, and an opening K5, corresponding to the upper surface of the inorganic matrix IOM included in the green light-emitting layer 25G, to remove the self-assembled monolayer 24 formed on the upper surface of the inorganic matrix IOM included in the red light-emitting layer 25R, and the self-assembled monolayer 24 formed on the upper surface of the inorganic matrix IOM included in the green light-emitting layer 25G. In this process step, light irradiation by the use of, for instance, a low-pressure mercury lamp (472 KJ/mol) having a wavelength of 254 nm is performed to disconnect part of the bonding between the self-assembled monomolecules 5, constituting the self-assembled monolayer 24, to cause the self-assembled monomolecules 5 to react with surrounding oxygen, so that the self-assembled monomolecules 5 can be decomposed and removed. Accordingly, additional process steps, such as development and rinse, do not have to be performed.

FIG. 10 is a plan view of the surface 24S of the self-assembled monolayer 24 included in the display device 1 according to the first embodiment.

As illustrated in FIG. 10, in the display device 1, no self-assembled monolayer 24 is formed on the upper surface of the inorganic matrix IOM, that is, on the upper surface of the red light-emitting layer 25R, the upper surface of the green light-emitting layer 25G, and the upper surface of the blue light-emitting layer 25B; thus, no self-assembled monolayer 24 having water repellency is formed on the upper surface of the red light-emitting layer 25R, the upper surface of the green light-emitting layer 25G, and the upper surface of the blue light-emitting layer 25B, thereby offering wide selection of materials for a layer that is to be formed directly on the light-emitting layer of each color.

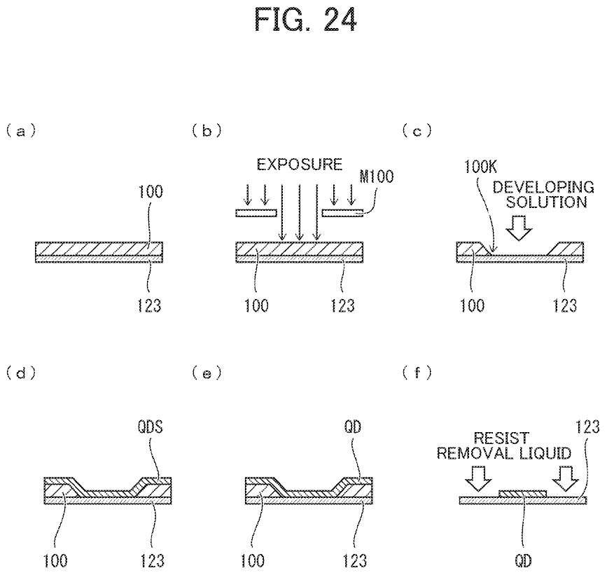

FIG. 24(a), FIG. 24(b), FIG. 24(c), FIG. 24(d), FIG. 24(e), and FIG. 24(f) illustrate a process step of liftoff using a normal resist layer 100 according to a comparative example.

The process step of liftoff using the normal resist layer 100 includes the following process steps for the light-emitting layer of each color: forming, as illustrated in FIG. 24(a), the normal resist layer 100 onto the hole transport layer 23, which is an underlayer; subjecting the normal resist layer 100 to exposure via a mask M100, as illustrated in FIG. 24(b); performing, as illustrated in FIG. 24(c), development using a developing solution for forming an opening 100K in the normal resist layer 100; applying a solution QDS containing quantum dots, as illustrated in FIG. 24(d); heating the solution QDS containing the quantum dots to obtain a light-emitting layer QD including the quantum dots, as illustrated in FIG. 24(e); and removing the normal resist layer 100 by the use of a resist removal liquid to subject the light-emitting layer QD to patterning, as illustrated in FIG. 24(f).

The foregoing method for manufacturing the display device 1 can omit, for the light-emitting layer of each color, the step in FIG. 24(c) of development using a developing solution, and the step in FIG. 24(f) of removing the normal resist layer 100 by the use of a resist removal liquid to subject the light-emitting layer QD to patterning, and this method can thus achieve simplified manufacturing process steps.

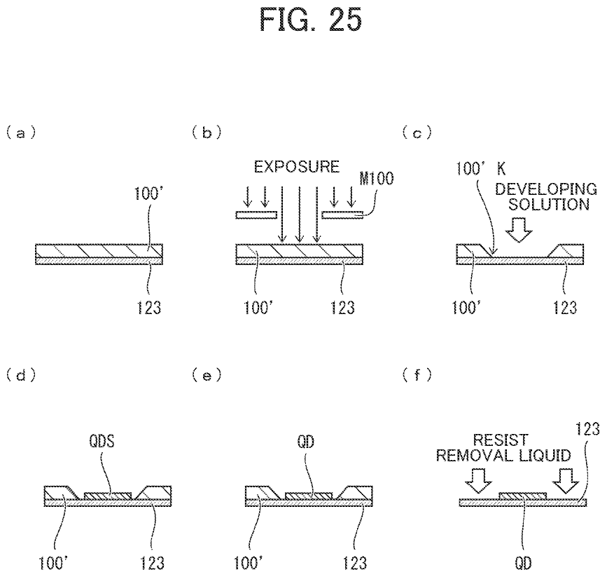

FIG. 25(a), FIG. 25(b), FIG. 25(c), FIG. 25(d), FIG. 25(e), and FIG. 25(f) illustrate a process step of liftoff using a liquid-repellent resist layer 100′ according to a comparative example.

The process step of liftoff using the liquid-repellent resist layer 100′ includes the following process steps for the light-emitting layer of each color: forming, as illustrated in FIG. 25(a), the liquid-repellent resist layer 100′ onto a hole transport layer 123, which is an underlayer; subjecting the liquid-repellent resist layer 100′ to exposure via the mask M100, as illustrated in FIG. 25(b); performing, as illustrated in FIG. 25(c), development using a developing solution for forming an opening 100′K in the liquid-repellent resist layer 100′; applying the solution QDS containing the quantum dots, as illustrated in FIG. 25(d); heating the solution QDS containing the quantum dots to obtain the light-emitting layer QD including the quantum dots, as illustrated in FIG. 25(e); and removing the liquid-repellent resist layer 100′ by the use of a resist removal liquid to subject the light-emitting layer QD to patterning, as illustrated in FIG. 25(f).

The foregoing method for manufacturing the display device 1 can omit, for the light-emitting layer of each color, the step in FIG. 25(c) of development using a developing solution, and the step in FIG. 25(f) of removing the liquid-repellent resist layer 100′ by the use of a resist removal liquid to subject the light-emitting layer QD to patterning, and this method can thus achieve simplified manufacturing process steps.

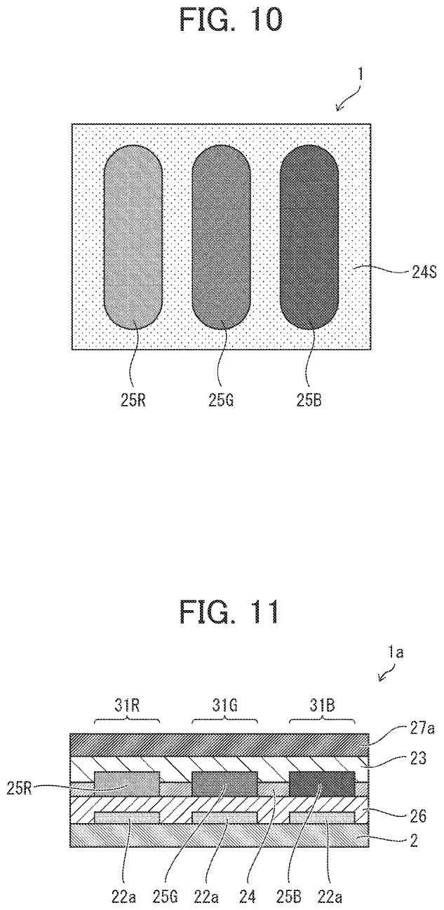

FIG. 11 is a sectional view of a schematic configuration of a red light-emitting element 31R, of a green light-emitting element 31G, and of a blue light-emitting element 31B all of which are included in a display device 1a according to a first modification of the first embodiment.

As illustrated in FIG. 11, the red light-emitting element 31R includes the first electrode 22a, the electron transport layer 26, the red light-emitting layer 25R, the hole transport layer 23, and a second electrode 27a in the stated order on the substrate 2 including the transistors TR. The green light-emitting element 31G includes the first electrode 22a, the electron transport layer 26, the green light-emitting layer 25G, the hole transport layer 23, and the second electrode 27a in the stated order on the substrate 2 including the transistors TR. The blue light-emitting element 31B includes the first electrode 22a, the electron transport layer 26, the blue light-emitting layer 25B, the hole transport layer 23, and the second electrode 27a in the stated order on the substrate 2 including the transistors TR.

In the display device 1a, an underlayer having a polar surface on which the self-assembled monolayer 24 is formed is the electron transport layer 26 made of ZnO. Thus, the distal end FG2 on the other side of the self-assembled monomolecule 5 coordinates with a metal cation of the electron transport layer 26.

The red light-emitting element 31R, green light-emitting element 31G, and blue light-emitting element 31B illustrated in FIG. 11 are of inverted stacked structure with the first electrode 22a being a cathode, and with the second electrode 27a being an anode; a top-emission light-emitting element can be achieved by forming the first electrode 22a, which is a cathode, with an electrode material that reflects visible light, and by forming the second electrode 27a, which is an anode, with an electrode material that transmits visible light.

The display device 1a can achieve a display device including light-emitting elements of inverted stacked structure.

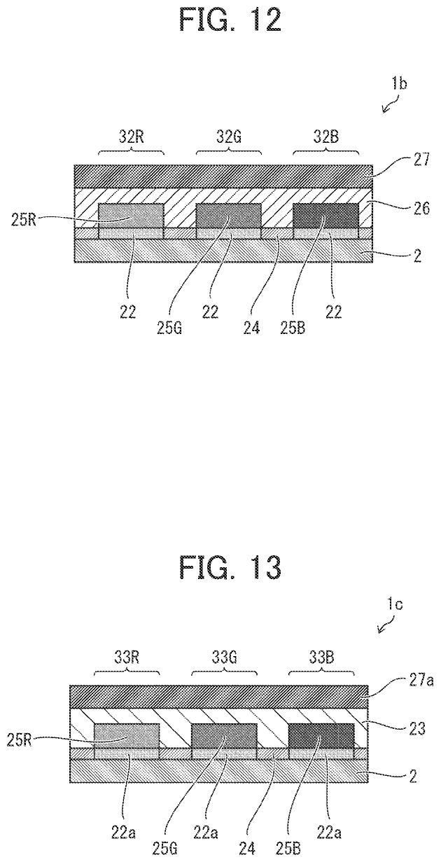

FIG. 12 is a sectional view of a schematic configuration of a red light-emitting element 32R, of a green light-emitting element 32G, and of a blue light-emitting element 32B all of which are included in a display device 1b according to a second modification of the first embodiment.

As illustrated in FIG. 12, the red light-emitting element 32R includes the first electrode 22, the red light-emitting layer 25R, the electron transport layer 26, and the second electrode 27 in the stated order on the substrate 2 including the transistors TR. The green light-emitting element 32G includes the first electrode 22, the green light-emitting layer 25G, the electron transport layer 26, and the second electrode 27 in the stated order on the substrate 2 including the transistors TR. The blue light-emitting element 32B includes the first electrode 22, the blue light-emitting layer 25B, the electron transport layer 26, and the second electrode 27 in the stated order on the substrate 2 including the transistors TR.

A top-emission light-emitting element can be achieved by forming the first electrode 22, which is an anode, with an electrode material that reflects visible light, and by forming the second electrode 27, which is a cathode, with an electrode material that transmits visible light.

In the display device 1b, an underlayer having a polar surface on which the self-assembled monolayer 24 is formed is the first electrode 22, and the substrate 2 including the transistors TR. Usable examples of the first electrode 22 include, but not limited to, a stack in which a metal material, such as Al, Mg, Li or Ag, and a transparent metal oxide (e.g., an indium tin oxide, an indium zinc oxide, and an indium gallium zinc oxide) are stacked in the stated order on the substrate 2 including the transistors TR, and a stack in which an alloy of the metal material and the transparent metal oxide are stacked in the stated order on the substrate 2 including the transistors TR. Further, a substrate with an Al₂O₃ insulating layer formed on the flattening film 21, which constitutes the surface 2S of the substrate 2 including the transistors TR illustrated in FIG. 2, can be used as the substrate 2 including the transistors TR. Thus, the distal end FG2 on the other side of the self-assembled monomolecule 5 coordinates with a metal cation of the first electrode 22, and a metal cation of the Al₂O₃ insulating layer formed on the substrate 2 including the transistors TR.

By using a material having hole transportability, such as NiO for instance, as an inorganic matrix, the display device 1b can achieve a display device including the following: the light-emitting element 32R of forward stacked structure provided with the red light-emitting layer 25R serving also as a hole transport layer; the light-emitting element 32G of forward stacked structure provided with the green light-emitting layer 25G serving also as a hole transport layer; and the light-emitting element 32B of forward stacked structure provided with the blue light-emitting layer 25B serving also as a hole transport layer. It is noted that the inorganic matrix in this case may be made of a material having an insulation capability further.

FIG. 13 is a sectional view of a schematic configuration of a red light-emitting element 33R, of a green light-emitting element 33G, and of a blue light-emitting element 33B all of which are included in a display device 1c according to a third modification of the first embodiment.

As illustrated in FIG. 13, the red light-emitting element 33R includes the first electrode 22a, the red light-emitting layer 25R, the hole transport layer 23, and the second electrode 27a in the stated order on the substrate 2 including the transistors TR. The green light-emitting element 33G includes the first electrode 22a, the green light-emitting layer 25G, the hole transport layer 23, and the second electrode 27a in the stated order on the substrate 2 including the transistors TR. The blue light-emitting element 33G includes the first electrode 22a, the blue light-emitting layer 25B, the hole transport layer 23, and the second electrode 27a in the stated order on the substrate 2 including the transistors TR.

The red light-emitting element 33R, green light-emitting element 33G, and blue light-emitting element 33B illustrated in FIG. 13 are of inverted stacked structure with the first electrode 22a being a cathode, and with the second electrode 27a being an anode; a top-emission light-emitting element can be achieved by forming the first electrode 22a, which is a cathode, with an electrode material that reflects visible light, and by forming the second electrode 27a, which is an anode, with an electrode material that transmits visible light.

In the display device 1c, an underlayer having a polar surface on which the self-assembled monolayer 24 is formed is the first electrode 22a, and the substrate 2 including the transistors TR. Usable examples of the first electrode 22a include, but not limited to, a metal material, such as Al, Mg, Li or Ag, and an alloy of the metal material. Further, a substrate with an Al₂O₃ insulating layer formed on the flattening film 21, which constitutes the surface 2S of the substrate 2 including the transistors TR illustrated in FIG. 2, can be used as the substrate 2 including the transistors TR. Thus, the distal end FG2 on the other side of the self-assembled monomolecule 5 coordinates with a metal atom of the first electrode 22a, and a metal cation of the Al₂O₃ insulating layer formed on the substrate 2 including the transistors TR.

By using a material having electron transportability, such as ZnO for instance, as an inorganic matrix, the display device 1c can achieve a display device including the following: the light-emitting element 33R of inverted stacked structure provided with the red light-emitting layer 25R serving also as an electron transport layer; the light-emitting element 33G of inverted stacked structure provided with the green light-emitting layer 25G serving also as an electron transport layer; and the light-emitting element 33B of inverted stacked structure provided with the blue light-emitting layer 25B serving also as an electron transport layer. It is noted that the inorganic matrix in this case may be made of a material having an insulation capability further.

### Second Embodiment

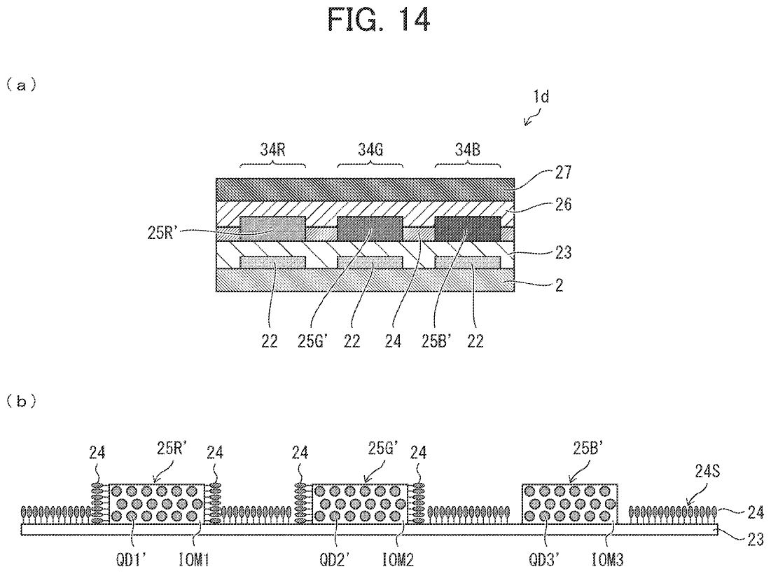

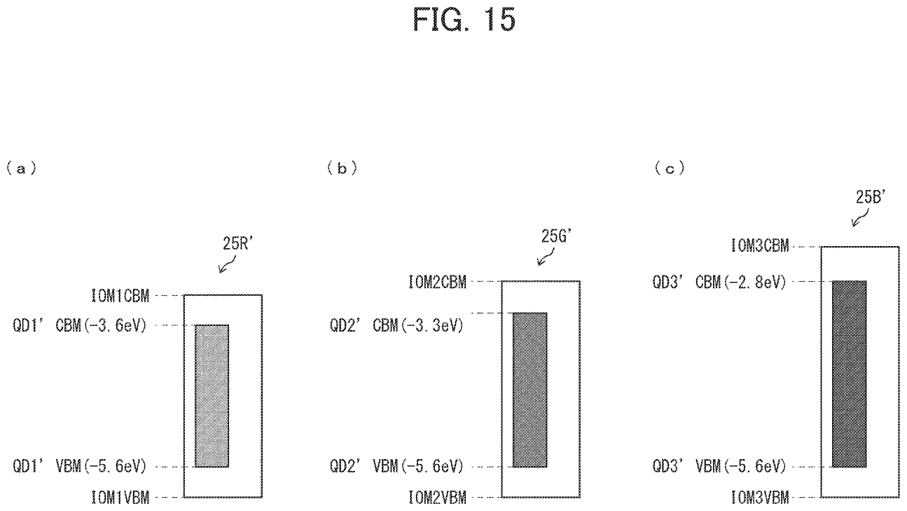

The following describes a second embodiment of the present disclosure on the basis of FIG. 14 through FIG. 17. A display device 1d according to this embodiment is different from the display devices described in the first embodiment in that a red light-emitting layer 25R′ includes a first inorganic matrix IOM1, that a green light-emitting layer 25G′ includes a second inorganic matrix IOM2 different from the first inorganic matrix IOM1, and that a blue light-emitting layer 25B′ includes a third inorganic matrix IOM3 different from the first inorganic matrix IOM1 and second inorganic matrix IOM2. The others are the same as those described in the first embodiment. For convenience in description, components having the same functions as those of the components illustrated in the drawings related to the first embodiment will be denoted by the same signs, and their description will be omitted.

FIG. 14(a) is a sectional view of a schematic configuration of a red light-emitting element 34R, of a green light-emitting element 34G, and of a blue light-emitting element 34B all of which are included in the display device 1d according to the second embodiment, and FIG. 14(b) is a sectional view of a schematic configuration of the red light-emitting layer 25R′, green light-emitting layer 25G′, and blue light-emitting layer 25B′ all of which are included in the display device 1d according to the second embodiment.

As illustrated in FIG. 14(a) and FIG. 14(b), the display device 1d, which is provided with the red light-emitting layer 25R′ including quantum dots QD1′ embedded in the first inorganic matrix IOM1, the green light-emitting layer 25G′ including quantum dots QD2′ embedded in the second inorganic matrix IOM2, and the blue light-emitting layer 25B′ including quantum dots QD3′ embedded in the third inorganic matrix IOM3, can reduce damage on the quantum dots QD1′, quantum dots QD2′, and quantum dots QD3′. In addition, the non-polar (water-repellent) surface of the self-assembled monolayer 24 can prevent deterioration that results from moisture entrance into the red light-emitting layer 25R′, green light-emitting layer 25G′, and blue light-emitting layer 25B′. In addition, the self-assembled monolayer 24, when formed on the red light-emitting layer 25R′, green light-emitting layer 25G′, and blue light-emitting layer 25B′, can prevent a defect in the red light-emitting layer 25R′, green light-emitting layer 25G′, and blue light-emitting layer 25B′.

It is noted that quantum dots of the same material (a core of CdSe, and a shell of ZnS) having different particle diameters are used in this embodiment in order for the quantum dots QD1′, the quantum dots QD2′, and the quantum dots QD3′ to emit different colors. For instance, a quantum dot having the largest particle diameter can be used as a red-emitting quantum dot, a quantum dot having the smallest particle diameter can be used as a blue-emitting quantum dot, and a quantum dot having a particle diameter falling between the particle diameter of the quantum dot used as the red-emitting quantum dot and the particle diameter of the quantum dot used as the blue-emitting quantum dot can be used as a green-emitting quantum dot. In this way, for forming a red-light-emitting quantum dot, a green-light-emitting quantum dot, and a blue-light-emitting quantum dot by the use of quantum dots of the same material, increase in band gap that results from a quantum effect is mainly obtained as the result of that the conduction band minimum (CBM) of a quantum dot becomes shallow.

FIG. 15(a) illustrates ideal band levels of the quantum dots QD1′ and first inorganic matrix IOM1 in the red light-emitting layer 25R′, FIG. 15(b) illustrates ideal band levels of the quantum dots QD2′ and second inorganic matrix IOM2 in the green light-emitting layer 25G′, and FIG. 15(c) illustrates ideal band levels of the quantum dots QD3′ and third inorganic matrix IOM3 in the blue light-emitting layer 25B′.

As illustrated in FIG. 15(a), FIG. 15(b), and FIG. 15(c), the band gap of the quantum dots QD3′ included in the blue light-emitting layer 25B′ is larger than the band gap of the quantum dots QD1′ included in the red light-emitting layer 25R′, and the band gap of the quantum dots QD2′ included in the green light-emitting layer 25G, and the band gap of the quantum dots QD2′ included in the green light-emitting layer 25G′ is larger than the band gap of the quantum dots QD1′ included in the red light-emitting layer 25R′.

The red light-emitting layer 25R′ included in the display device 1d is structured, as illustrated in FIG. 15(a), such that the valence band maximum (VBM) of the first inorganic matrix IOM1 is deeper than the valence band maximum (VBM) of the quantum dots QD1′, and such that the conduction band minimum (CBM) of the first inorganic matrix IOM1 is shallower than the conduction band minimum (CBM) of the first quantum dots QD1′.

The green light-emitting layer 25G′ included in the display device 1d is structured, as illustrated in FIG. 15(b), such that the valence band maximum (VBM) of the second inorganic matrix IOM2 is deeper than the valence band maximum (VBM) of the quantum dots QD2′, and such that the conduction band minimum (CBM) of the second inorganic matrix IOM2 is shallower than the conduction band minimum (CBM) of the second quantum dots QD2′.

The blue light-emitting layer 25B′ included in the display device 1d is structured, as illustrated in FIG. 15(c), such that the valence band maximum (VBM) of the third inorganic matrix IOM3 is deeper than the valence band maximum (VBM) of the quantum dots QD3′, and such that the conduction band minimum (CBM) of the third inorganic matrix IOM3 is shallower than the conduction band minimum (CBM) of the third quantum dots QD3′.

As illustrated in FIG. 15(a), FIG. 15(b), and FIG. 15(c), the display device 1d is structured such that the conduction band minimum (CBM) of the third inorganic matrix IOM3 is shallower than the conduction band minimum (CBM) of the first inorganic matrix IOM1, and the conduction band minimum (CBM) of the second inorganic matrix IOM2, and such that the conduction band minimum (CBM) of the second inorganic matrix IOM2 is shallower than the conduction band minimum (CBM) of the first inorganic matrix IOM1.

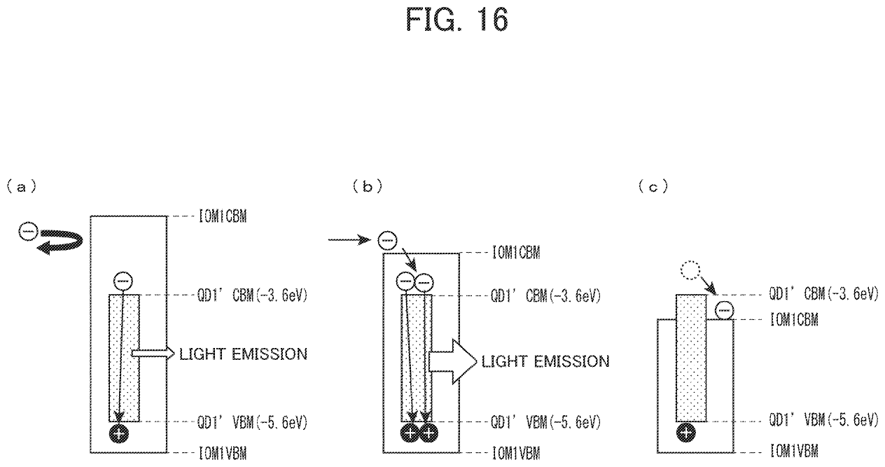

FIG. 16(a) and FIG. 16(c) illustrate an instance where the positional relationship between the band level of the quantum dot and the band level of the inorganic matrix is not ideal, and FIG. 16(b) illustrates an instance where the positional relationship between the band level of the quantum dot and the band level of the inorganic matrix is ideal.

As illustrated in FIG. 16(a), when the minimum of the conduction band CBM of the first inorganic matrix IOM1 is excessively high, that is, when the first inorganic matrix IOM1 has a much higher conduction band minimum (CBM) than the conduction band minimum (CBM) of the quantum dots QD1′, electrons are less likely to be injected into the quantum dots QD1′, thus increasing voltage.

As illustrated in FIG. 16(c), when the conduction band minimum (CBM) of the first inorganic matrix IOM1 is excessively low, that is, when the first inorganic matrix IOM1 has a lower conduction band minimum (CBM) than the conduction band minimum (CBM) of the quantum dots QD1′, or a conduction band minimum (CBM) close to the conduction band minimum (CBM) of the first quantum dots QD1′, electrons move to the conduction band CB of the first inorganic matrix IOM1 for a deeper level and cannot thus recombine with holes within the quantum dots QD1′. Such a problem occurs in holes similarly; although not illustrated, the problem also occurs when the first inorganic matrix IOM1 has a higher valence band maximum (VBM) than the valence band maximum (VBM) of the quantum dots QD1′, or a valence band maximum (VBM) close to the valence band maximum (VBM) of the quantum dots QD1′.

As illustrated in FIG. 16(b), when the band level of the quantum dots QD1′ and the band level of the first inorganic matrix IOM1 are ideal, excitons within the quantum dots QD1′ can recombine without leaking to the outside, and in addition, electrons are sufficiently injected into the quantum dots QD1′.

The illustration in FIG. 16 is shown using the first inorganic matrix IOM1 and the quantum dots QD1; this principle is applied as is to the second inorganic matrix IOM2 and quantum dots QD2′, and to the third inorganic matrix IOM3 and quantum dots QD3′.

In this embodiment, the first inorganic matrix IOM1 is made of Sc₂O₃ (CBM of −1.63 ev, VBM of −8.04 ev) having a crystal system equivalent to Bixbyite, the second inorganic matrix IOM2 is made of Y₂O₃ (CBM of −1.19 ev, and VBM of −7.76 ev) having a crystal system equivalent to Bixbyite, and the third inorganic matrix IOM3 is made of La₂O₃ (CBM of −0.90 ev, and VBM of −6.65 ev) having a crystal system equivalent to Bixbyite, so that the band level of the quantum dots and the band level of the inorganic matrix are ideal in the red light-emitting layer 25R′, the green light-emitting layer 25G′, and the blue light-emitting layer 25B′.

The display device 1d, which is structured, as illustrated in FIG. 16(b), such that the band level of the quantum dots and the band level of the inorganic matrix are ideal in the red light-emitting layer 25R′, the green light-emitting layer 25G′, and the blue light-emitting layer 25B′, can prevent the effect of excess voltage rise and can avoid electrons within the quantum dots from moving to the inorganic matrix.

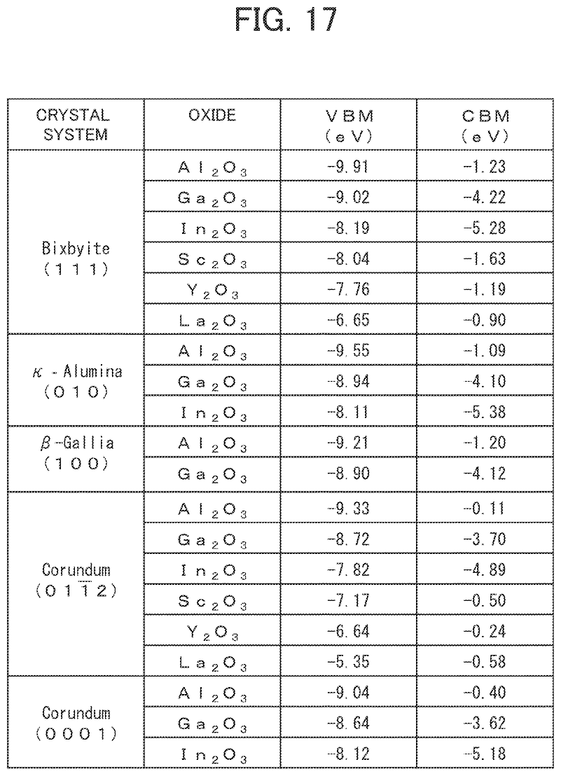

FIG. 17 illustrates the band levels of respective oxides.

This embodiment describes, by way of example, an instance where for the quantum dots QD1′, quantum dots QD2′, and quantum dots QD3′ of the same material (a core of CdSe, and a shell of ZnS) having different particle diameters, the first inorganic matrix IOM1 is made of Sc₂O₃ having a crystal system equivalent to Bixbyite, where the second inorganic matrix IOM2 is made of Y₂O₃ having a crystal system equivalent to Bixbyite, and where the third inorganic matrix IOM3 is made of La₂O₃ having a crystal system equivalent to Bixbyite.

For instance, the first inorganic matrix IOM1, the second inorganic matrix IOM2, and the third inorganic matrix IOM3 can be formed by appropriately using the individual oxides shown in FIG. 17 in such a manner that the band level of the quantum dots and the band level of the inorganic matrix illustrated in FIG. 16(b) become ideal in accordance with a quantum dot that is used. It is noted that the first inorganic matrix IOM1, the second inorganic matrix IOM2, and the third inorganic matrix IOM3 can be formed from an inorganic material precursor in a solution process using the polar solvent PSO.

### Third Embodiment

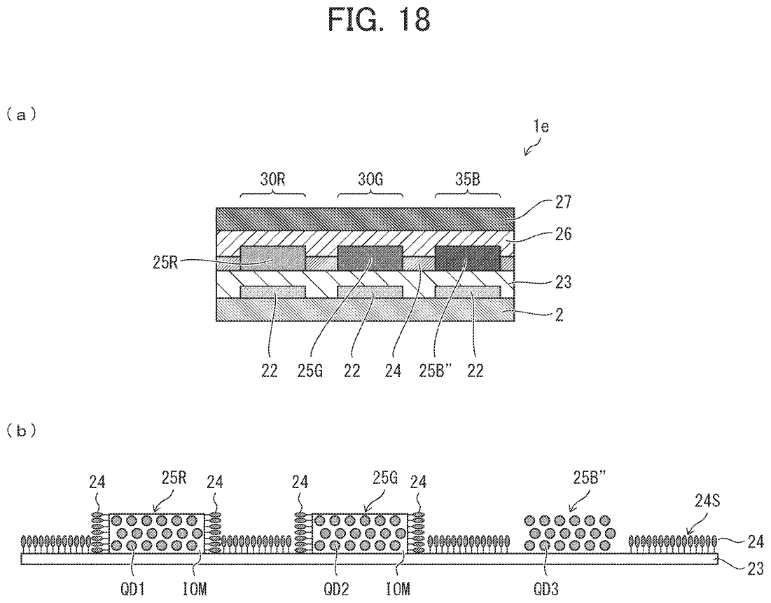

The following describes a third embodiment of the present disclosure on the basis of FIG. 18. A display device 1e according to this embodiment is different from the display devices described in the first and second embodiments in that a blue light-emitting layer 25B″, which is a light-emitting layer that is formed last of all the process steps of forming the light-emitting layers, includes no inorganic matrix. The others are the same as those described in the first and second embodiments. For convenience in description, components having the same functions as those of the components illustrated in the drawings related to the first and second embodiments will be denoted by the same signs, and their description will be omitted.

Although this embodiment describes, by way of example, an instance where the red light-emitting layer 25R, the green light-emitting layer 25G, and the blue light-emitting layer 25B″ are formed in the stated order, and where a light-emitting layer that is formed last of all the process steps of forming the light-emitting layers is the blue light-emitting layer 25B″, the order of forming the red light-emitting layer, green light-emitting layer, and blue light-emitting layer can be determined as appropriate as long as the light-emitting layer that is formed last of all the process steps of forming the light-emitting layers includes no inorganic matrix.

FIG. 18(a) is a sectional view of a schematic configuration of the red light-emitting element 30R, of the green light-emitting element 30G, and of a blue light-emitting element 35B all of which are included in the display device 1e according to the third embodiment, and FIG. 18(b) is a sectional view of a schematic configuration of the red light-emitting layer 25R, green light-emitting layer 25G, and blue light-emitting layer 25B″ all of which are included in the display device 1e according to the third embodiment.

As illustrated in FIG. 18(a) and FIG. 18(b), the blue light-emitting layer 25B″, which is a light-emitting layer that is formed last of all the process steps of forming the light-emitting layers, includes no inorganic matrix IOM. That is, the blue light-emitting layer 25B″ is composed of the quantum dots QD3.

A method for manufacturing the display device 1e includes the following process steps: the process steps in FIG. 4(a) through FIG. 8(a), which are the same as the process steps for manufacturing the display device 1 and are described in the first embodiment; after them, forming the quantum-dot-QD3 application solution containing the quantum dots QD3 and the polar solvent PSO selectively in the third polar surface region, which is described in the first embodiment; and after the process step of forming the quantum-dot-QD3 application solution, forming the blue light-emitting layer 25B″ composed of the quantum dots QD3, by removing the polar solvent POS.

In the display device 1e, the blue light-emitting layer 25B″, which is formed after the red light-emitting layer 25R and the green light-emitting layer 25G are formed, can be formed using only the quantum dots QD3. The blue light-emitting layer 25B″ including the quantum dots QD3 that emit blue light has a high voltage inherently that is necessary for light emission, and hence, the blue light-emitting layer 25B″ involves further voltage rise if it includes an inorganic matrix. Accordingly, the display device 1e can prevent voltage rise in the blue light-emitting layer 25B″ and can thus reduce the difference between the voltage necessary for the blue light-emitting layer 25B″ to emit light, and voltages necessary for the red light-emitting layer 25R and green light-emitting layer 25G to emit light.

Furthermore, the display device 1e enables the amount of heat generation in the blue light-emitting layer 25B″ during the driving of the display device 1e to be equal to the amount of heat generation in the red light-emitting layer 25R and green light-emitting layer 25G and thus enables the degree of deterioration in the blue light-emitting layer 25B″ to be as small as the degree of deterioration in the red light-emitting layer 25R and green light-emitting layer 25G. This can reduce a color shift even after the display device is driven for a long time as a full-color display that emits light of three colors.

In addition, the method for manufacturing the display device 1e can achieve a further simplified method for manufacturing a display device.

### Fourth Embodiment

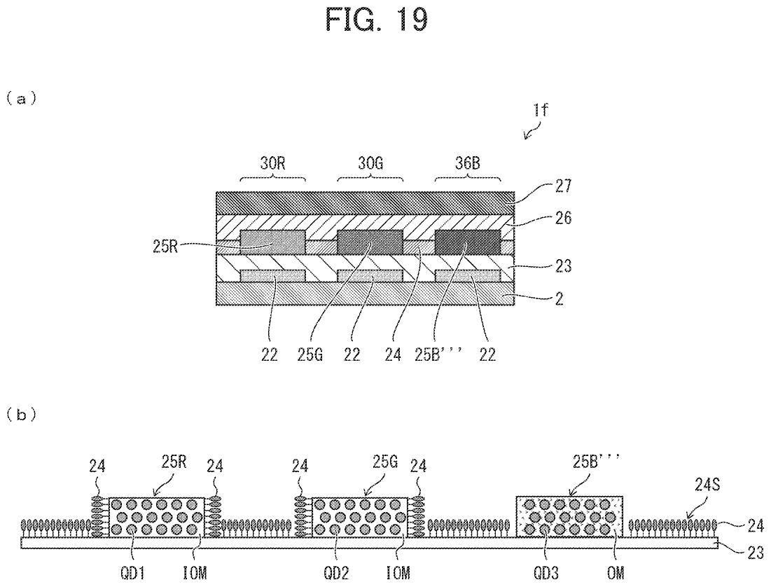

The following describes a fourth embodiment of the present disclosure on the basis of FIG. 19. A display device 1f according to this embodiment is different from the display devices described in the first to third embodiments in that a blue light-emitting layer 25B′″, which is a light-emitting layer that is formed last of all the process steps of forming the light-emitting layers, includes the quantum dots QD3 embedded in a matrix OM containing an organic material. The others are the same as those described in the first to third embodiments. For convenience in description, components having the same functions as those of the components illustrated in the drawings related to the first to third embodiments will be denoted by the same signs, and their description will be omitted.

Although this embodiment describes, by way of example, an instance where the red light-emitting layer 25R, the green light-emitting layer 25G, and the blue light-emitting layer 25B′″ are formed in the stated order, and where a light-emitting layer that is formed last of all the process steps of forming the light-emitting layers is the blue light-emitting layer 25B′″, the order of forming the red light-emitting layer, green light-emitting layer, and blue light-emitting layer can be determined as appropriate as long as the light-emitting layer that is formed last of all the process steps of forming the light-emitting layers includes quantum dots embedded in the material OM containing the organic material.

FIG. 19(a) is a sectional view of a schematic configuration of the red light-emitting element 30R, of the green light-emitting element 30G, and of a blue light-emitting element 36B all of which are included in the display device 1f according to the fourth embodiment, and FIG. 19(b) is a sectional view of a schematic configuration of the red light-emitting layer 25R, green light-emitting layer 25G, and blue light-emitting layer 25B′″ all of which are included in the display device 1f according to the fourth embodiment.

As illustrated in FIG. 19(a) and FIG. 19(b), the blue light-emitting layer 25B′″, which is a light-emitting layer that is formed last of all the process steps of forming the light-emitting layers, includes the quantum dots QD3 embedded in the material OM containing the organic material.

A method for manufacturing the display device 1f includes the following process steps: the process steps in FIG. 4(a) through FIG. 8(a), which are the same as the process steps for manufacturing the display device 1 and are described in the first embodiment; after them, forming the quantum-dot-QD3 application solution containing the quantum dots QD3, a precursor containing an organic material, and the polar solvent PSO selectively in the third polar surface region, which is described in the first embodiment; and after the process step of forming the quantum-dot-QD3 application solution, forming, by performing at least one of heating and light irradiation, the blue light-emitting layer 25B″ including the quantum dots QD3 embedded in the material OM containing the organic material formed by curing the precursor containing the organic material.

The matrix OM included in the display device 1f and containing the organic material may be made of a material with which the self-assembled monolayer 24 cannot be formed on its surface. For instance, the matrix OM containing the organic material may be made of an organic material, or a material containing an organic material. Furthermore, the matrix OM containing the organic material is preferably made of an organic insulating material, or a material containing an organic insulating material. Examples of the organic insulating material, or the material containing the organic insulating material include, but not limited to, polyvinyl alcohol (PVA), polystyrene (PS), polyacrylate, polyvinylpyrrolidone (PCP), carboxymethylcellulose (CMC), polymethylmethacrylate (PMMA), polysilsesquioxane (PSQ), and polydimethylsiloxane (PDMS).

The method for manufacturing the display device 1f is simple because it includes, in only the formation of the last light-emitting layer, no baking at as high a temperature as that in a process step of decomposing an inorganic material precursor, and no light irradiation at as high energy as that in this step.

The display device 1f enables the material OM containing the organic material to protect the quantum dots QD3, thus preventing deterioration in the quantum dots QD3.

Although each of the first to fourth embodiments has described a self-assembled monolayer as one example of a molecular film, as described above, the molecular film is not limited to a self-assembled monolayer; a film composed of molecules, that is, a molecular film can exert a similar effect unless otherwise inconsistent. Nevertheless, the molecular film is preferably a self-assembled monolayer, that is, the molecules preferably have the capability of self-assembly. This is because that the molecular film can be formed through a simple method, such as applying a solution with molecules dissolved in a solvent onto a target application layer. It is noted that the molecular film is preferably structured such that a plurality of identical molecules are arranged side by side. That is, a monolayer is preferable. This is because that the identical molecules form thickness, thus enabling the molecular film to have a substantially uniform thickness, and that the molecular film, which is composed of identical molecules, has substantially uniform film quality, and that the molecular film is structured such that identical molecules are adjacent to each other, so that the molecules can be distributed densely within the film. Furthermore, the molecules constituting the molecular film are preferably arranged at regular intervals between the adjacent molecules because such an arrangement enables a further dense distribution. Further, the molecules constituting the molecular film are preferably arranged in the same orientation because such an arrangement enables a further dense distribution, thus enabling more firm bonding by interaction. Further, a molecular film having all the foregoing configurations, that is, a self-assembled monolayer with a plurality of identical molecules arranged side by side, with the adjacent molecules being at regular intervals, and with the molecules arranged in the same orientation is the most desirable. It is noted that the molecular film is not limited to a single-layer molecular film; a stacked structure of molecules can be provided by a particular procedure using a well-known method. Such a stacked structure of molecules is preferable because it enables a thicker molecular film or a thicker stacked film of molecules, thus enabling film thickness regulation.

### Fifth Embodiment

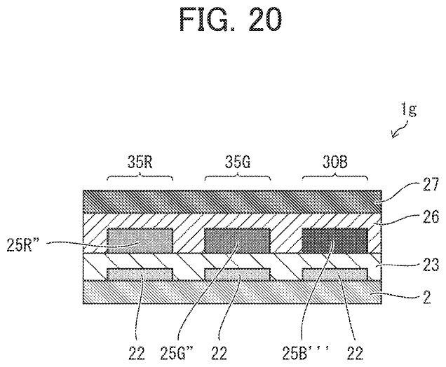

The following describes a fifth embodiment of the present disclosure on the basis of FIG. 20 through FIG. 23. A display device 1g according to this embodiment is different from the display devices described in the first to fourth embodiments in that this display device includes no self-assembled monolayer 24 composed of the self-assembled monomolecule 5. The others are the same as those described in the first to fourth embodiments. For convenience in description, components having the same functions as those of the components illustrated in the drawings related to the first to fourth embodiments will be denoted by the same signs, and their description will be omitted.

FIG. 20 is a sectional view of a schematic configuration of a red light-emitting element 35R, of a green light-emitting element 35G, and of the blue light-emitting element 30B all of which are included in the display device 1g according to the fifth embodiment.

As illustrated in FIG. 20, the display device 1g includes no self-assembled monolayer 24 composed of the self-assembled monomolecule 5.

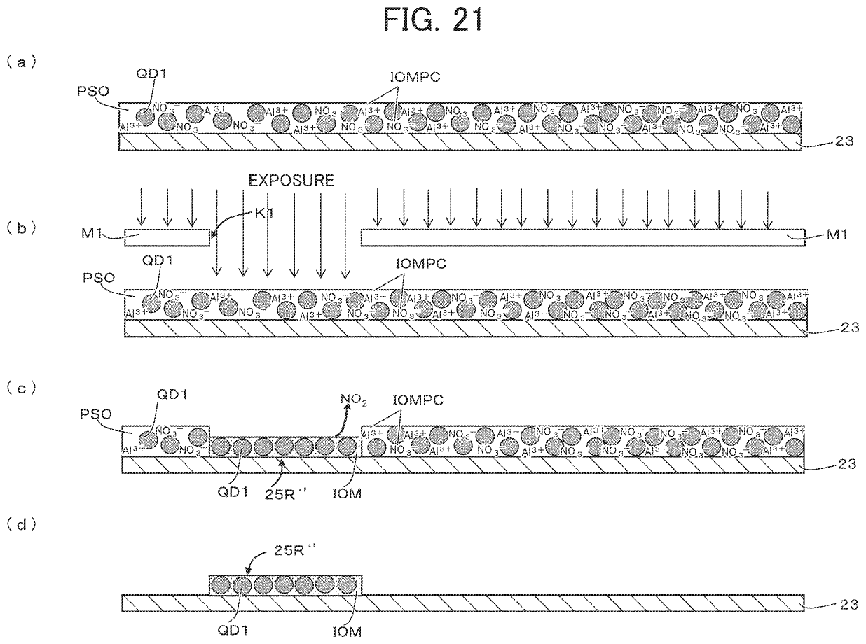

FIG. 21(a), FIG. 21(b), FIG. 21(c), and FIG. 21(d) illustrate some of process steps for manufacturing the display device 1g.

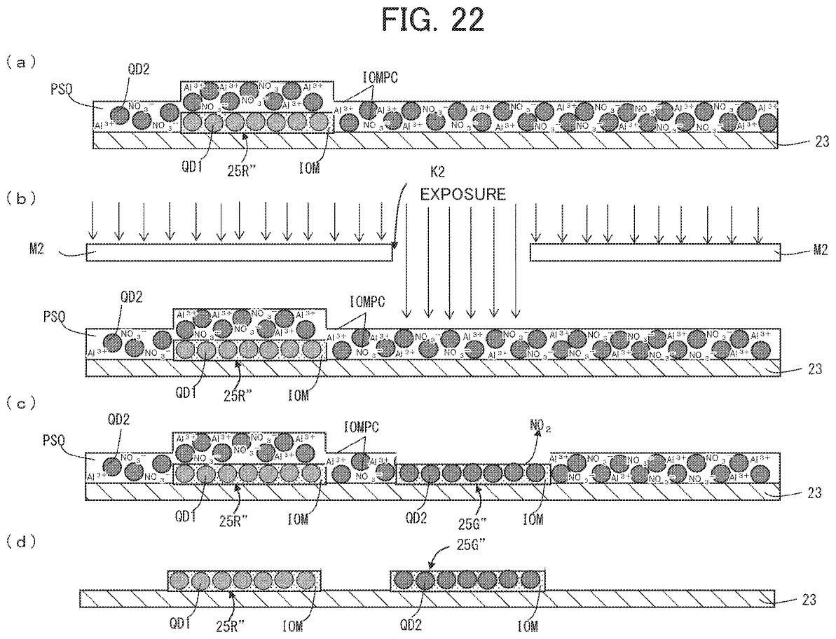

FIG. 22(a), FIG. 22(b), and FIG. 22(c) illustrate some of the process steps for manufacturing the display device 1g that are performed after the process step illustrated in FIG. 21(d).

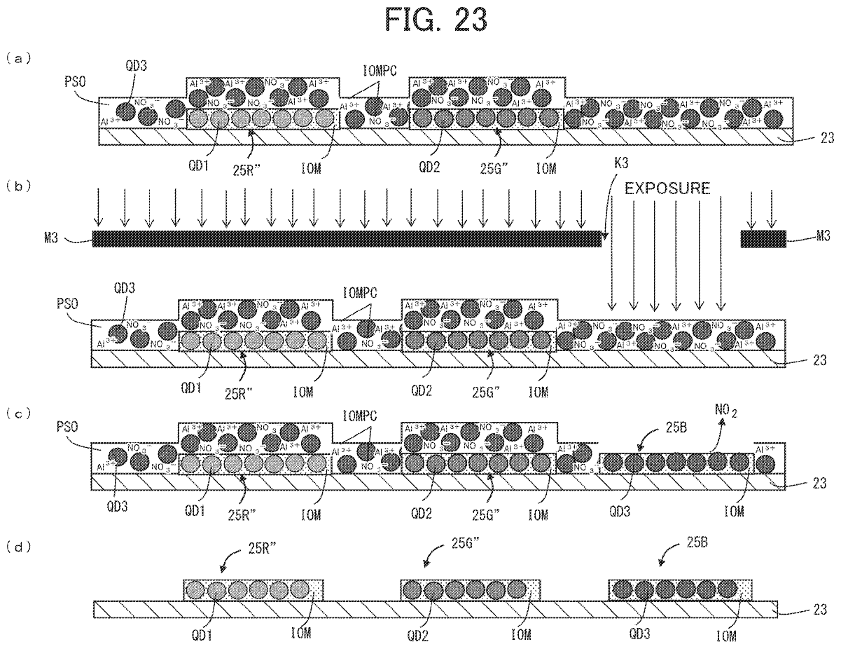

FIG. 23(a), FIG. 23(b), and FIG. 23(c) illustrate some of the process steps for manufacturing the display device 1g that are performed after the process step illustrated in FIG. 22(d).

As illustrated in FIG. 21(a), the first process step is forming the quantum-dot-QD1 application solution containing the quantum dots QD1, inorganic material precursors IOMPC, and polar solvent PSO all over the polar surface 23S of the hole transport layer 23, which is an underlayer made of NiO. As illustrated in FIG. 21(b), the next is pre-baking the quantum-dot-QD1 application solution formed on the polar surface 23S of the hole transport layer 23, followed by irradiating a region in which a red light-emitting layer 25R″ is to be formed, with light via the mask M1 having the opening K1, thus, as illustrated in FIG. 21(c), obtaining the red light-emitting layer 25R″ that is a cured portion in the quantum-dot-QD1 application solution corresponding to the region in which the red light-emitting layer 25R″ is to be formed.

As illustrated in FIG. 21(d), the next is development using, for instance, DMSO or DMF, both of which are polar solvents, to remove an uncured portion in the quantum-dot-QD1 application solution, thus obtaining only the red light-emitting layer 25R″.

As illustrated in FIG. 22(a), the next is forming the quantum-dot-QD2 application solution containing the quantum dots QD2, inorganic material precursors IOMPC, and polar solvent PSO all over the polar surface 23S of the hole transport layer 23, which is an underlayer made of NiO, and all over the red light-emitting layer 25R″. As illustrated in FIG. 22(b), the next is pre-baking the quantum-dot-QD2 application solution, followed by irradiating a region in which a green light-emitting layer 25G″ is to be formed, with light via the mask M2 having the opening K2, thus, as illustrated in FIG. 22(c), obtaining the green light-emitting layer 25G″ that is a cured portion in the quantum-dot-QD2 application solution corresponding to the region in which the green light-emitting layer 25G″ is to be formed. As illustrated in FIG. 22(d), the next is development using, for instance, DMSO or DMF, both of which are polar solvents, to remove an uncured portion in the quantum-dot-QD2 application solution, thus obtaining the red light-emitting layer 25R″ and the green light-emitting layer 25G″.

As illustrated in FIG. 23(a), the next is forming the quantum-dot-QD3 application solution containing the quantum dots QD3, inorganic material precursors IOMPC, and polar solvent PSO all over the polar surface 23S of the hole transport layer 23, which is an underlayer made of NiO, and all over the red light-emitting layer 25R″ and the green light-emitting layer 25G″. As illustrated in FIG. 23(b), the next is pre-baking the quantum-dot-QD3 application solution, followed by irradiating a region in which the blue light-emitting layer 25B is to be formed, with light via the mask M3 having the opening K3, thus, as illustrated in FIG. 23(c), obtaining the blue light-emitting layer 25B that is a cured portion in the quantum-dot-QD3 application solution corresponding to the region in which the blue light-emitting layer 25B is to be formed. As illustrated in FIG. 23(d), the next is development using, for instance, DMSO or DMF, both of which are polar solvents, to remove an uncured portion in the quantum-dot-QD3 application solution, thus obtaining the red light-emitting layer 25R″, the green light-emitting layer 25G″, and the blue light-emitting layer 25B. It is noted that in the forgoing light irradiation (exposure step), the target portion can be cured through, for instance, 40-minute or longer exposure using a 1-kW UV lamp that emits an exposure wavelength of 200 nm or less.

Although this embodiment describes, by way of example, an instance where the red light-emitting layer 25R″, the green light-emitting layer 25G″, and the blue light-emitting layer 25B individually include amorphous Al₂O₃ as the inorganic matrix IOM, the red light-emitting layer 25R″, the green light-emitting layer 25G″, and the blue light-emitting layer 25B may individually include inorganic matrixes made of different materials. For instance, the red light-emitting layer 25R″ may include the quantum dots QD1′ and first inorganic matrix IOM1 described in the second embodiment, the green light-emitting layer 25G″ may include the quantum dots QD2′ and second inorganic matrix IOM2 described in the second embodiment, and the blue light-emitting layer 25B may include the quantum dots QD3′ and third inorganic matrix IOM3 described in the second embodiment.

The display device 1g, which is structured such that its quantum dots are embedded and protected in the inorganic matrixes, can reduce damage on the quantum dots.

In addition, the method for manufacturing the display device 1g enables the red light-emitting layer 25R″, green light-emitting layer 25G″, and blue light-emitting layer 25B each including the quantum dots embedded in the inorganic matrix to be formed without the use of the resist layer and self-assembled monolayer 24, and this method can thus achieve simplified manufacturing process steps.

As described above, this embodiment describes, by way of example, an instance where the red light-emitting layer 25R″, the green light-emitting layer 25G″, and the blue light-emitting layer 25B are formed through partial light irradiation to leave only the cured portions.

For instance, energy necessary for the curing may be obtained by heat, and the red light-emitting layer 25R″, the green light-emitting layer 25G″, and the blue light-emitting layer 25B may be formed through partial heating to leave only the cured portions.

### Additional Note

The present disclosure is not limited to the foregoing embodiments. Various modifications can be made within the scope of the claims. An embodiment that is obtained in combination as appropriate with the technical means disclosed in the respective embodiments is also included in the technical scope of the present disclosure. Furthermore, combining the technical means disclosed in the respective embodiments can form a new technical feature.

### INDUSTRIAL APPLICABILITY

The present disclosure is usable for a display device and a method for manufacturing a display device.

1. A method for manufacturing a display device, comprising the steps of:
forming a self-assembled monolayer using a self-assembled monomolecule whose distal end on one side is a non-polar functional group onto a polar surface of an underlayer to form a non-polar region that is a surface of the self-assembled monolayer;
forming a first polar surface region that is the polar surface of the underlayer, by light irradiation to remove a part of the self-assembled monolayer;
forming a first-quantum-dot application solution containing a first quantum dot, a first inorganic material precursor, and a polar solvent selectively in the first polar surface region; and
after the step of forming the first-quantum-dot application solution, forming a first light-emitting layer including the first quantum dot embedded in a first inorganic matrix composed of the first inorganic material precursor, by performing at least one of heating and light irradiation.

2. The method for manufacturing the display device according to claim 1, comprising the steps of:
after the step of forming the first light-emitting layer, forming a self-assembled monolayer composed of a self-assembled monomolecule whose distal end on one side is a non-polar functional group onto at least a surface of the first light-emitting layer;
forming a second polar surface region that is the polar surface of the underlayer, by light irradiation to remove another part of the self-assembled monolayer different from the first polar surface region;
forming a second-quantum-dot application solution containing a second quantum dot, a second inorganic material precursor, and a polar solvent selectively in the second polar surface region, the second quantum dot being different from the first quantum dot in emission peak wavelength; and
after the step of forming the second-quantum-dot application solution, forming a second light-emitting layer including the second quantum dot embedded in a second inorganic matrix composed of the second inorganic material precursor, by performing at least one of heating and light irradiation.

3. The method for manufacturing the display device according to claim 2, comprising the steps of:
after the step of forming the second light-emitting layer, forming a self-assembled monolayer composed of a self-assembled monomolecule whose distal end on one side is a non-polar functional group onto at least a surface of the second light-emitting layer;
forming a third polar surface region that is the polar surface of the underlayer, by light irradiation to remove further another part of the self-assembled monolayer different from the first polar surface region and the second polar surface region;
forming a third-quantum-dot application solution containing a third quantum dot, a third inorganic material precursor, and a polar solvent selectively in the third polar surface region, the third quantum dot being different from the first quantum dot and the second quantum dot in emission peak wavelength; and
after the step of forming the third-quantum-dot application solution, forming a third light-emitting layer including the third quantum dot embedded in a third inorganic matrix composed of the third inorganic material precursor, by performing at least one of heating and light irradiation.

4. The method for manufacturing the display device according to claim 2, comprising the steps of:
after the step of forming the second light-emitting layer, forming a self-assembled monolayer composed of a self-assembled monomolecule whose distal end on one side is a non-polar functional group onto at least a surface of the second light-emitting layer;
forming a third polar surface region that is the polar surface of the underlayer, by light irradiation to remove further another part of the self-assembled monolayer different from the first polar surface region and the second polar surface region;
forming a third-quantum-dot application solution containing a third quantum dot and a polar solvent selectively in the third polar surface region, the third quantum dot being different from the first quantum dot and the second quantum dot in emission peak wavelength; and
after the step of forming the third-quantum-dot application solution, forming a third light-emitting layer composed of the third quantum dot by removing the polar solvent.

5. The method for manufacturing the display device according to claim 2, comprising the steps of:
after the step of forming the second light-emitting layer, forming a self-assembled monolayer composed of a self-assembled monomolecule whose distal end on one side is a non-polar functional group onto at least a surface of the second light-emitting layer;
forming a third polar surface region that is the polar surface of the underlayer, by light irradiation to remove further another part of the self-assembled monolayer different from the first polar surface region and the second polar surface region;
forming a third-quantum-dot application solution containing a third quantum dot, a precursor containing an organic material, and a polar solvent selectively in the third polar surface region, the third quantum dot being different from the first quantum dot and the second quantum dot in emission peak wavelength; and
after the step of forming the third-quantum-dot application solution, forming, by performing at least one of heating and light irradiation, a third light-emitting layer including the third quantum dot embedded in a matrix containing an organic material formed by curing the precursor containing the organic material.

6. The method for manufacturing the display device according to claim 3, further comprising the step of irradiating the self-assembled monolayer formed on an upper surface of the first light-emitting layer, and the self-assembled monolayer formed on an upper surface of the second light-emitting layer with light to remove the self-assembled monolayer formed on the upper surface of the first light-emitting layer, and the self-assembled monolayer formed on the upper surface of the second light-emitting layer.

7. The method for manufacturing the display device according to claim 1, wherein the step of forming the first light-emitting layer includes forming the first inorganic matrix with a metal oxide.

8. (canceled)

9. The method for manufacturing the display device according to claim 1, wherein
the step of forming the first-quantum-dot application solution uses, as the first quantum dot, a quantum dot having a surface containing ZnS, and
the step of forming the first light-emitting layer includes forming the first light-emitting layer including the first quantum dot embedded in the first inorganic matrix containing an yttrium oxide.

10. The method for manufacturing the display device according to claim 1, wherein
the step of forming the first-quantum-dot application solution uses, as the first quantum dot, a quantum dot having a surface containing ZnS, and
the step of forming the first light-emitting layer includes epitaxially growing an yttrium oxide from the ZnS to form the first light-emitting layer including the first quantum dot embedded in the first inorganic matrix containing the yttrium oxide.

11.-19. (canceled)

20. A display device comprising:
a first light-emitting layer including a first quantum dot embedded in a first inorganic matrix; and
a molecular film composed of molecules adjacent to each other, and having a non-polar surface, the molecules each having a distal end on one side that is a non-polar functional group.

21. (canceled)

22. The display device according to claim 20, wherein the first inorganic matrix is a metal oxide.

23. The display device according to claim 20, wherein the first inorganic matrix is an oxide containing one or more of Ti, Nb, Al, Si, Mg, Ta, Hf, Zr, Y, La, and Sr.

24. The display device according to claim 20, wherein
the first quantum dot has a surface containing ZnS, and
the first inorganic matrix contains an yttrium oxide.

25. The display device according 20, wherein
the first quantum dot has a surface containing ZnS, and
the first inorganic matrix contains an yttrium oxide epitaxially grown from the ZnS.

26.-28. (canceled)

29. The display device according 20, wherein
the first inorganic matrix is a silicon oxide, and
the molecules each have a distal end on another side containing organic silane.

30. The display device according 20, wherein the first inorganic matrix is an amorphous substance.

31. The display device according 20, further comprising:
a second light-emitting layer including a second quantum dot embedded in a second inorganic matrix; and
a third light-emitting layer including a third quantum dot embedded in a third inorganic matrix,
wherein the second quantum dot is different from the first quantum dot and the third quantum dot in emission peak wavelength, and
the third quantum dot is different from the first quantum dot in emission peak wavelength.

32.-33. (canceled)

34. The display device according 20, further comprising:
a second light-emitting layer including a second quantum dot embedded in a second inorganic matrix; and
a third light-emitting layer composed of a third quantum dot,
wherein the second quantum dot is different from the first quantum dot and the third quantum dot in emission peak wavelength, and
the third quantum dot is different from the first quantum dot in emission peak wavelength.

35. The display device according 20, further comprising:
a second light-emitting layer including a second quantum dot embedded in a second inorganic matrix; and
a third light-emitting layer including a third quantum dot embedded in a matrix containing an organic material,
wherein the second quantum dot is different from the first quantum dot and the third quantum dot in emission peak wavelength, and
the third quantum dot is different from the first quantum dot in emission peak wavelength.

36.-38. (canceled)

39. A display device comprising:
a first light-emitting layer including a first quantum dot embedded in a first inorganic matrix;
a second light-emitting layer including a second quantum dot embedded in a second inorganic matrix; and
a third light-emitting layer including a third quantum dot embedded in a third inorganic matrix,
wherein a band gap of the third quantum dot is larger than a band gap of the first quantum dot, and a band gap of the second quantum dot,
the band gap of the second quantum dot is larger than the band gap of the first quantum dot,
a valence band maximum of the first inorganic matrix is deeper than a valence band maximum of the first quantum dot,
a conduction band minimum of the first inorganic matrix is shallower than a conduction band minimum of the first quantum dot,
a valence band maximum of the second inorganic matrix is deeper than a valence band maximum of the second quantum dot,
a conduction band minimum of the second inorganic matrix is shallower than a conduction band minimum of the second quantum dot,
a valence band maximum of the third inorganic matrix is deeper than a valence band maximum of the third quantum dot,
a conduction band minimum of the third inorganic matrix is shallower than a conduction band minimum of the third quantum dot,
the conduction band minimum of the third inorganic matrix is shallower than the conduction band minimum of the first inorganic matrix, and the conduction band minimum of the second inorganic matrix, and
the conduction band minimum of the second inorganic matrix is shallower than the conduction band minimum of the first inorganic matrix.
